(19) United States
(12) Patent Application Publication
(10) Pub. No.: US 2026/0269788 A1
(43) Pub. Date: Sep. 10, 2026

(54) TRACKER CIRCUIT

(71) Applicant: Murata Manufacturing Co, Ltd., Nagaokakyo-shi (JP)

(72) Inventors: KOUJI YAMAGUCHI, Nagaokakyo-shi (JP); Muneharu KATO, Nagaokakyo-shi (JP); Atsushi HIRONO, Nagaokakyo-shi (JP); Seiko NETSU, Nagaokakyo-shi (JP)

(21) Appl. No.: 19/662,169

(22) Filed: Apr. 29, 2026

Related U.S. Application Data
(63) Continuation of application No. PCT/JP2024/035529, filed on Oct. 3, 2024.

(30) Foreign Application Priority Data
Dec. 22, 2023 (JP) 2023-216882

(51) Int. Cl. H03F 1/02; H02M 3/07

(52) U.S. Cl. CPC H03F 1/0227; H02M 3/07; H03F 2200/102; H03F 2200/105; H03F 2200/451

(57) ABSTRACT

A tracker circuit includes a switched-capacitor circuit that is configured to generate, in a first mode, multiple first discrete voltages from an input voltage and generate, in a second mode, multiple second discrete voltages from the input voltage; and a supply modulator configured to selectively output, to a power amplifier, at least one of the multiple first discrete voltages that have been generated or at least one of the multiple second discrete voltages that have been generated. A first number of the multiple first discrete voltages is greater than a second number of the multiple second discrete voltages.

### CROSS REFERENCE TO RELATED APPLICATIONS

This application is a continuation of International Application No. PCT/JP2024/035529, filed October 3, 2024, which claims priority to Japanese Patent Application No. 2023-216882, filed December 22, 2023, the entire contents of each of which are hereby incorporated by reference in their entirety.

### TECHNICAL FIELD

The present disclosure relates to a tracker circuit.

### BACKGROUND

In recent years, envelope tracking (ET) has been applied to power amplifier circuits in order to improve power efficiency. For example, United States Patent No. 9,755,672 discloses a digital envelope tracking (D-ET) mode that selectively supplies multiple discrete voltages in accordance with an envelope signal.

### SUMMARY OF INVENTION

However, power efficiency in the D-ET mode may decrease as the peak-to-average power ratio (PAPR) of a radio frequency (RF) signal increases.

Accordingly, the exemplary aspects of the present disclosure provide a tracker circuit configured to improving power efficiency in the D-ET mode.

According to an exemplary aspect, a tracker circuit is provided that includes a switched-capacitor circuit configured to generate multiple discrete voltages from an input voltage; and a supply modulator configured to selectively output, to a power amplifier, at least one of the multiple discrete voltages that have been generated. The switched- capacitor circuit includes a first flying capacitor, a second flying capacitor, a third flying capacitor, and a fourth flying capacitor; a first smoothing capacitor, a second smoothing capacitor, and a third smoothing capacitor; and a first switch, a second switch, a third switch, a fourth switch, a fifth switch, a sixth switch, a seventh switch, an eighth switch, a ninth switch, a tenth switch, an eleventh switch, a twelfth switch, a thirteenth switch, and a fourteenth switch. One end (a first end) of the first switch and one end (a first end) of the second switch are connected to one (a first electrode) of two electrodes of the first flying capacitor. One end (a first end) of the third switch and one end (a first end) of the fourth switch are connected to one (a first electrode) of two electrodes of the second flying capacitor. One end (a first end) of the fifth switch and one end (a first end) of the sixth switch are switchably connected to another (a second electrode) of the two electrodes of the first flying capacitor via the thirteenth switch, and are connected to one (a first electrode)of two electrodes of the third flying capacitor. One end (a first end) of the seventh switch and one end (a first end) of the eighth switch are switchably connected to another (a second electrode) of the two electrodes of the second flying capacitor via the fourteenth switch, and are connected to one (a first electrode) of two electrodes of the fourth flying capacitor. One end (a first end) of the ninth switch and one end (a first end) of the tenth switch are connected to another (a second electrode) of the two electrodes of the third flying capacitor. One end (a first end) of the eleventh switch and one end (a first end) of the twelfth switch are connected to another (a second electrode) of the two electrodes of the fourth flying capacitor. Another end (a second end) of the first switch, another end (a second end) of the third switch, and one (a first electrode) of two electrodes of the first smoothing capacitor are connected to ground. Another end (a second end) of the second switch, another end (a second end) of the fourth switch, another end (a second end) of the fifth switch, and another end (a second end) of the seventh switch are connected to another (a second electrode) of the two electrodes of the first smoothing capacitor and one (a first electrode) of two electrodes of the second smoothing capacitor. Another end (a second end) of the sixth switch, another end (a second end) of the eighth switch, another end (a second end) of the ninth switch, and another end (a second end) of the eleventh switch are connected to another (a second electrode) of the two electrodes of the second smoothing capacitor and one (a first electrode) of two electrodes of the third smoothing capacitor. Another end (a second end) of the tenth switch and another end (a second end) of the twelfth switch are connected to another (a second electrode) of the two electrodes of the third smoothing capacitor. One end (a first end) of the thirteenth switch is connected to the other (the second electrode) of the two electrodes of the first flying capacitor. Another end (a second end) of the thirteenth switch is connected to the one (the first electrode) of the two electrodes of the third flying capacitor. One end (a first end) of the fourteenth switch is connected to the other (the second electrode) of the two electrodes of the second flying capacitor. Another end (a second end) of the fourteenth switch is connected to the one (the first electrode) of the two electrodes of the fourth flying capacitor.

In another exemplary aspect, a tracker circuit includes a switched-capacitor circuit configured to generate multiple discrete voltages from an input voltage; and a supply modulator configured to selectively output, to a power amplifier, at least one of the multiple discrete voltages that have been generated. The switched-capacitor circuit includes a first flying capacitor, a second flying capacitor, a third flying capacitor, and a fourth flying capacitor; a first smoothing capacitor, a second smoothing capacitor, and a third smoothing capacitor; and a first switch, a second switch, a third switch, a fourth switch, a fifth switch, a sixth switch, a seventh switch, an eighth switch, a ninth switch, a tenth switch, an eleventh switch, a twelfth switch, and a thirteenth switch. One end (a first end) of the first switch and one end (a first end) of the second switch are connected to one (a first electrode) of two electrodes of the first flying capacitor. One end (a first end) of the third switch and one end (a first end) of the fourth switch are connected to one (a first electrode) of two electrodes of the second flying capacitor. One end (a first end) of the fifth switch and one end (a first end) of the sixth switch are connected to another (a second electrode) of the two electrodes of the first flying capacitor and one (a first electrode) of two electrodes of the third flying capacitor. One end (a first end) of the seventh switch and one end (a first end) of the eighth switch are connected to another (a second electrode) of the two electrodes of the second flying capacitor and one (a first electrode) of two electrodes of the fourth flying capacitor. One end (a first end) of the ninth switch and one end (a first end) of the tenth switch are connected to another (a second electrode) of the two electrodes of the third flying capacitor. One end (a first end) of the eleventh switch and one end (a first end) of the twelfth switch are connected to another (a second electrode) of the two electrodes of the fourth flying capacitor. Another end (a second end) of the first switch, another end (a second end) of the third switch, and one (a first electrode) of two electrodes of the first smoothing capacitor are connected to each other. Another end (a second end) of the second switch, another end (a second end) of the fourth switch, another end (a second end) of the fifth switch, and another end (a second end) of the seventh switch are connected to another (a second electrode) of the two electrodes of the first smoothing capacitor and one (a first electrode) of two electrodes of the second smoothing capacitor. Another end (a second end) of the sixth switch, another end (a second end) of the eighth switch, another end (a second end) of the ninth switch, and another end (a second end) of the eleventh switch are connected to another (a second electrode) of the two electrodes of the second smoothing capacitor and one (a first electrode) of two electrodes of the third smoothing capacitor. Another end (a second end) of the tenth switch and another end (a second end) of the twelfth switch are connected to another (a second electrode) of the two electrodes of the third smoothing capacitor. One end (a first end) and another end (a second end) of the thirteenth switch are respectively connected to the one (the first electrode) and the other (the second electrode) of the two electrodes of the first smoothing capacitor, the second smoothing capacitor, or the third smoothing capacitor.

In another exemplary aspect, a tracker circuit includes a switched-capacitor circuit that is configured to generate , in a first mode, multiple first discrete voltages from an input voltage and generate , in a second mode, multiple second discrete voltages from the input voltage; and a supply modulator configured to selectively output, to a power amplifier, at least one of the multiple first discrete voltages that have been generated or at least one of the multiple second discrete voltages that have been generated. A first number of the multiple first discrete voltages is greater than a second number of the multiple second discrete voltages.

According to the present disclosure, power efficiency can be improved in the D-ET mode.

### BRIEF DESCRIPTION OF DRAWINGS

FIG. 1A is a graph illustrating an example of changes in a power supply voltage in an average power tracking (APT) mode.

FIG. 1B is a graph illustrating an example of changes in a power supply voltage in an analog envelope tracking (A-ET) mode.

FIG. 1C is a graph illustrating an example of changes in a power supply voltage in a digital envelope tracking (D-ET) mode.

FIG. 2 is a circuit configuration diagram of a communication device according to a first exemplary embodiment.

FIG. 3 is a circuit configuration diagram of a tracker circuit according to the first exemplary embodiment.

FIG. 4A is a circuit configuration diagram illustrating a connection state in a first phase of a first mode of a switched-capacitor circuit according to the first exemplary embodiment.

FIG. 4B is a circuit configuration diagram illustrating a connection state in a second phase of the first mode of the switched-capacitor circuit according to the first exemplary embodiment.

FIG. 5A is a circuit configuration diagram illustrating a connection state in a first phase of a second mode of the switched-capacitor circuit according to the first exemplary embodiment.

FIG. 5B is a circuit configuration diagram illustrating a connection state in a second phase of the second mode of the switched-capacitor circuit according to the first exemplary embodiment.

FIG. 6 is a diagram illustrating an example of multiple discrete voltages generated by the switched-capacitor circuit according to the first exemplary embodiment.

FIG. 7 is a graph illustrating an example of temporal changes in power supply voltages supplied to a power amplifier by the tracker circuit according to the first exemplary embodiment.

FIG. 8 is a graph illustrating an example of temporal changes in power supply voltages supplied to the power amplifier by the tracker circuit according to the first exemplary embodiment.

FIG. 9 is a circuit configuration diagram of a switched-capacitor circuit according to a modification of the first exemplary embodiment.

FIG. 10 is a circuit configuration diagram of a communication device according to a second exemplary embodiment.

FIG. 11 is a circuit configuration diagram of a switched-capacitor circuit according to the second exemplary embodiment.

FIG. 12A is a circuit configuration diagram illustrating a connection state in a first phase of a first mode of the switched-capacitor circuit according to the second exemplary embodiment.

FIG. 12B is a circuit configuration diagram illustrating a connection state in a second phase of the first mode of the switched-capacitor circuit according to the second exemplary embodiment.

FIG. 13A is a circuit configuration diagram illustrating a connection state in a first phase of a second mode of the switched-capacitor circuit according to the second exemplary embodiment.

FIG. 13B is a circuit configuration diagram illustrating a connection state in a second phase of the second mode of the switched-capacitor circuit according to the second exemplary embodiment.

FIG. 14 is a diagram illustrating an example of multiple discrete voltages generated by the switched-capacitor circuit according to the second exemplary embodiment.

FIG. 15 is a circuit configuration diagram of a switched-capacitor circuit according to a modification of the second exemplary embodiment.

### DETAILED DESCRIPTION OF EXEMPLARY EMBODIMENTS

Hereinafter, exemplary embodiments of the present disclosure will be described in detail with reference to the drawings. The exemplary embodiments described below each illustrate a general or specific example. The numerical values, shapes, materials, constituent elements, the disposition and connection manner of the constituent elements, and so forth described in the following exemplary embodiments are merely examples, and are not intended to limit the present disclosure.

The drawings are schematic diagrams drawn with emphasis, omission, or ratio adjustment performed as appropriate in order to illustrate exemplary aspects of the present disclosure. Thus, it is noted that the illustration therein is not necessarily strict, and may be different from actual shapes, positional relationships, and ratios. In the drawings, constituent elements that are substantially the same are denoted by the same reference numerals, and a repeated description thereof may be omitted or simplified.

In a circuit configuration, the term "connected" includes not only a direct connection using a connection terminal and/or a wiring conductor, but also an electrical connection via another circuit element. The expression "A is switchably connected to B" indicates that the connection and disconnection between A and B can be switched, and that A is connected to B via a switch. The expression "A is connected to B" includes "A is switchably connected to B". The expression "C is connected between A and B" indicates that one end of C is connected to A and the other end of C is connected to B, and that C is disposed in series to a path connecting A and B. The expression "path connecting A and B" indicates a path composed of a conductor that electrically connects A to B.

In the following description, a term "terminal" refers to a point at which a conductor in an element terminates. In a case where the impedance of a conductor between elements is sufficiently low, a terminal is interpreted as not only a single point but also any point on the conductor between the elements or the entire conductor.

In addition, terms indicating the relationships between elements, such as "parallel" and "perpendicular", terms indicating the shapes of elements, such as "rectangular", and numerical ranges do not represent only their strict literal meaning, but include substantially equivalent ranges, for example, an error of about several percent.

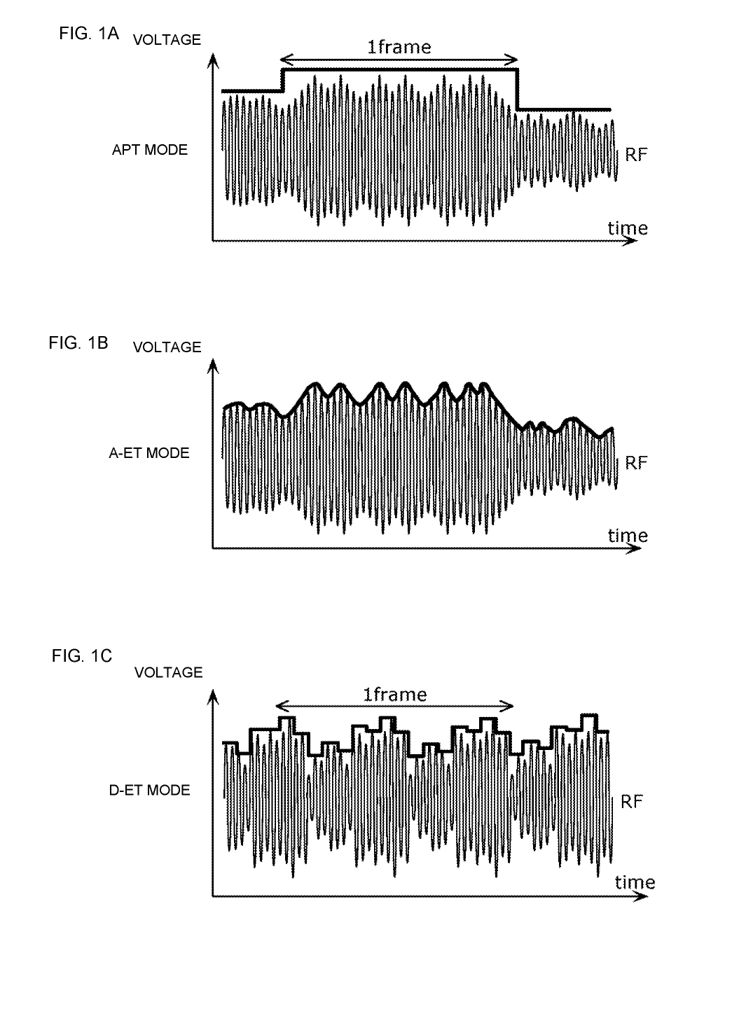

First, a description will be given of tracking modes of supplying a power amplifier with a power supply voltage dynamically regulated based on a radio frequency (RF) signal over time, which are techniques of amplifying the RF signal with high efficiency. A tracking mode is a mode of dynamically regulating a power supply voltage to be applied to a power amplifier. Among several types of tracking modes, an average power tracking (APT) mode, an analog envelope tracking (A-ET) mode, and a digital envelope tracking (D-ET) mode will be described here with reference to FIG. 1A, FIG. 1B, and FIG. 1C. In FIG. 1A, FIG. 1B, and FIG. 1C, the horizontal axis represents time, and the vertical axis represents voltage. A thick solid line represents a power supply voltage, and a thin solid line (waveform) represents a modulated signal.

FIG. 1A is a graph illustrating an example of changes in the power supply voltage in the APT mode. In the APT mode in FIG. 1A, the power supply voltage is varied, based on an average power, to multiple discrete voltage levels in units of one frame.

For purposes of this disclosure, a frame refers to a unit constituting an RF signal (modulated signal). For example, in 5th Generation New Radio (5G NR) and Long Term Evolution (LTE), a frame includes ten subframes, each subframe includes multiple slots, and each slot includes multiple symbols. The subframe has a length of 1 ms, and the frame has a length of 10 ms.

A mode of varying a voltage level in units of one frame or in units larger than one frame based on an average power is referred to as an APT mode, which is distinguished from a mode of varying a voltage level in units smaller than one frame (for example, in units of subframes, slots, or symbols). For example, a mode of varying a voltage level in units of symbols is referred to as a symbol power tracking (SPT) mode, which is distinguished from the APT mode.

FIG. 1B is a graph illustrating an example of changes in the power supply voltage in the A-ET mode. In the A-ET mode, the power supply voltage is continuously varied based on an envelope signal, and thus the envelope of a modulated signal is tracked.

The envelope signal is a signal indicating the envelope of a modulated signal. An envelope value is represented by, for example, the square root of (I² + Q²). (I, Q) represents a constellation point herein. The constellation point is a point representing a digitally modulated signal on a constellation diagram. (I, Q) is determined by a baseband integrated circuit (BBIC), for example, based on transmission information.

FIG. 1C is a graph illustrating an example of changes in the power supply voltage in the D-ET mode. In the D-ET mode, the power supply voltage is varied, based on an envelope signal, to multiple discrete voltage levels within one frame, and thus the envelope of a modulated signal is tracked. That is, in D-ET, the power supply voltage varies at a time interval shorter than in APT.

### FIRST EXEMPLARY EMBODIMENT

Hereinafter, a first exemplary embodiment will be described.

### 1.1 Circuit configuration of communication device 7

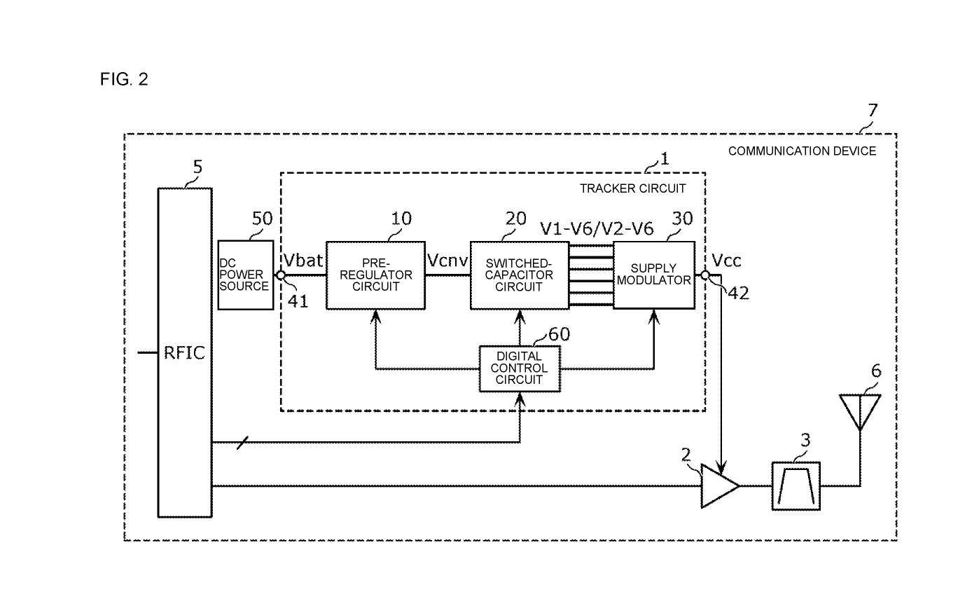

First, the circuit configuration of a communication device 7 according to the present exemplary embodiment will be described with reference to FIG. 2. FIG. 2 is a circuit configuration diagram of the communication device 7 according to the present exemplary embodiment.

FIG. 2 illustrates an exemplary circuit configuration. The communication device 7 can be implemented by using any of a wide variety of circuit implementations and circuit techniques. Thus, the description of the communication device 7 provided below is not to be construed in a limiting manner.

The communication device 7 according to the present exemplary embodiment can be used to provide wireless connections. For example, the communication device 7 can be implemented in a user terminal (user equipment (UE)) in a cellular network, such as a mobile phone, a smartphone, a tablet computer, or a wearable device. In another example, the communication device 7 can be implemented to provide wireless connections to an Internet of Things (IoT) sensor device, a medical/health-care device, a vehicle, an unmanned aerial vehicle (UAV) (a so-called drone), or an automated guided vehicle (AGV). In yet another example, the communication device 7 can be implemented to provide wireless connections at a wireless access point or a wireless hotspot.

As illustrated in FIG. 2, the communication device 7 includes a tracker circuit 1, a power amplifier 2, a filter 3, a radio frequency integrated circuit (RFIC) 5, an antenna 6, and a direct current (DC) power source 50.

The tracker circuit 1 is configured to supply a power supply voltage Vcc to the power amplifier 2 in the D-ET mode. Furthermore, the tracker circuit 1 may supply the power supply voltage Vcc to the power amplifier 2 in the APT mode. As illustrated in FIG. 2, the tracker circuit 1 includes a pre-regulator circuit 10, a switched-capacitor circuit 20, a supply modulator 30, an input terminal 41, an output terminal 42, and a digital control circuit 60.

The input terminal 41 is a terminal for receiving a DC voltage Vbat from the DC power source 50. The input terminal 41 is connected to the DC power source 50 outside the tracker circuit 1 and is connected to the pre-regulator circuit 10 inside the tracker circuit 1.

The output terminal 42 is a terminal for supplying the power supply voltage Vcc to the power amplifier 2. The output terminal 42 is connected to the power amplifier 2 outside the tracker circuit 1 and is connected to the supply modulator 30 inside the tracker circuit 1.

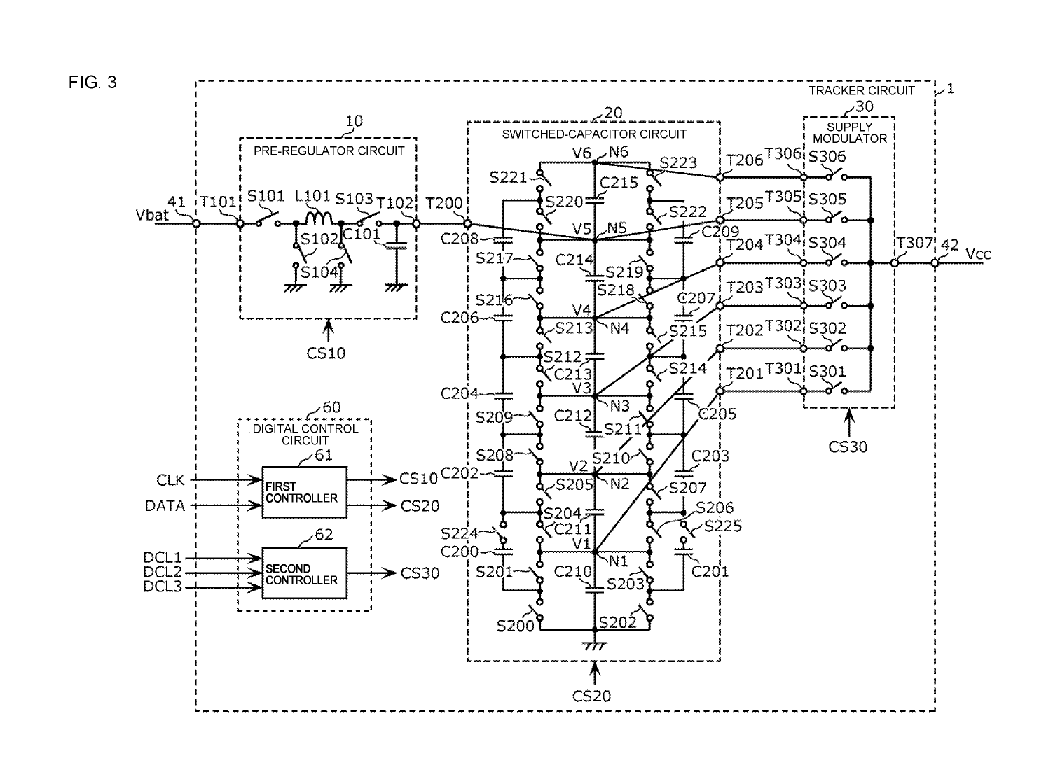

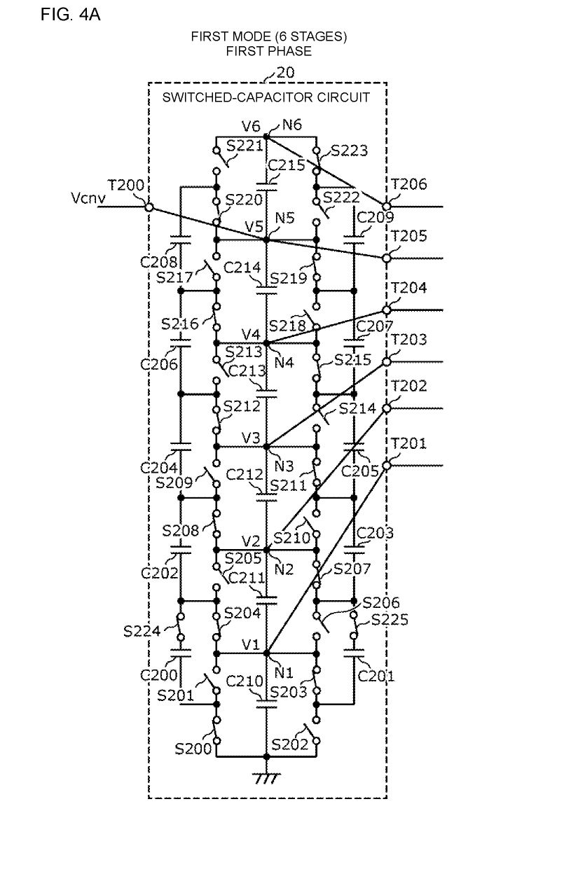

The pre-regulator circuit 10 may also be referred to as a magnetic regulator or a DC-DC converter. In the present exemplary embodiment, the pre-regulator circuit 10 is a one-input one-output buck-boost converter and is configured to convert the DC voltage Vbat into a regulated voltage Vcnv. The pre-regulator circuit 10 may be a buck converter or a boost converter. The pre-regulator circuit 10 is configured to chang, based on a control signal from the RFIC 5, for example, the regulated voltage Vcnv. A detailed circuit configuration of the pre-regulator circuit 10 will be described below with reference to FIG. 3. A part or the entirety of the pre-regulator circuit 10 does not necessarily have to be included in the tracker circuit 1.

The switched-capacitor circuit 20 is configured to generate, based on the regulated voltage Vcnv supplied by the pre-regulator circuit 10, multiple discrete voltages V1, V2, V3, V4, V5, and V6, or V2, V3, V4, V5, and V6. In some examples, the switched-capacitor circuit 20 has a first mode that generates multiple discrete voltages V1, V2, V3, V4, V5, and V6 (an example of multiple first discrete voltages) from the regulated voltage Vcnv, and a second mode that generates multiple discrete voltages V2, V3, V4, V5, and V6 (an example of multiple second discrete voltages) from the regulated voltage Vcnv. In this case, the number of the multiple discrete voltages V1, V2, V3, V4, V5, and V6 generated in the first mode is greater than the number of the multiple discrete voltages V2, V3, V4, V5, and V6 generated in the second mode. A detailed circuit configuration of the switched-capacitor circuit 20 will be described below with reference to FIG. 3.

The supply modulator 30 is configured to selectively output, as the power supply voltage Vcc, at least one of the multiple discrete voltages generated by the switched-capacitor circuit 20 to the power amplifier 2. That is, the supply modulator 30 is configured to select at least one voltage from among the multiple discrete voltages and supply the selected voltage to the power amplifier 2. A detailed circuit configuration of the supply modulator 30 will be described below with reference to FIG. 3.

The digital control circuit 60 is configured to control, based on a digital control signal from the RFIC 5, the pre-regulator circuit 10, the switched-capacitor circuit 20, and the supply modulator 30. In some examples, the digital control circuit 60 is configured to generate and output control signals CS10 and CS20 for controlling the switches included in the pre-regulator circuit 10 and the switched-capacitor circuit 20 and a control signal CS30 for controlling the switches included in the supply modulator 30. The circuit configuration of the digital control circuit 60 will be described below with reference to FIG. 3. A part or the entirety of the digital control circuit 60 does not necessarily have to be included in the tracker circuit 1.

The DC power source 50 is connected to the input terminal 41 of the tracker circuit 1. The DC power source 50 is configured to supply the DC voltage Vbat to the tracker circuit 1. The DC power source 50 may be, but is not limited to, a rechargeable battery, for example.

The power amplifier 2 is connected between the RFIC 5 and the filter 3. The power amplifier 2 is further connected to the tracker circuit 1. The power amplifier 2 is configured to amplify an RF signal supplied from the RFIC 5 by using the power supply voltage Vcc supplied from the tracker circuit 1.

The filter 3 is connected between the power amplifier 2 and the antenna 6. The filter 3 is a band pass filter having a pass band including a predetermined band. The predetermined band is a frequency band for a communication system constructed by using radio access technology (RAT), and is predefined by standardizing bodies (for example, 3rd Generation Partnership Project (3GPP, registered trademark), Institute of Electrical and Electronics Engineers (IEEE), and so forth). Examples of the communication system include a 5G NR system, an LTE system, and a Wireless Local Area Network (WLAN) system.

The antenna 6 transmits an RF signal that has passed through the filter 3. The antenna 6 does not necessarily have to be included in the communication device 7.

The circuit configuration of the communication device 7 illustrated in FIG. 2 is illustrative and is not restrictive. For example, the communication device 7 may include a baseband signal processing circuit that performs signal processing by using a frequency band lower than the frequency of an RF signal.

### 1.2 Circuit configuration of tracker circuit 1

Next, the circuit configuration of the tracker circuit 1 will be described with reference to FIG. 3. FIG. 3 is a circuit configuration diagram of the tracker circuit 1 according to the present exemplary embodiment.

FIG. 3 illustrates an exemplary circuit configuration. The tracker circuit 1 can be implemented by using any of a wide variety of circuit implementations and circuit techniques. Thus, the description of the tracker circuit 1 provided below is not to be construed in a limiting manner.

As described above, the tracker circuit 1 includes the pre-regulator circuit 10, the switched-capacitor circuit 20, the supply modulator 30, and the digital control circuit 60. The tracker circuit 1 may include a pulse shaping network (PSN) or a filter circuit (both not illustrated) between the supply modulator 30 and the output terminal 42.

Hereinafter, the circuit configurations of the pre-regulator circuit 10, the switched-capacitor circuit 20, the supply modulator 30, and the digital control circuit 60 will be described in order.

### 1.2.1 Circuit configuration of pre-regulator circuit 10

First, the circuit configuration of the pre-regulator circuit 10 will be described with reference to FIG. 3.

The pre-regulator circuit 10 includes an input terminal T101, an output terminal T102, switches S101 to S104, a power inductor L101, and a capacitor C101.

The input terminal T101 is a terminal for receiving the DC voltage Vbat. The input terminal T101 is connected to the input terminal 41 outside the pre-regulator circuit 10 and is connected to the switch S101 inside the pre-regulator circuit 10.

The output terminal T102 is a terminal for supplying the regulated voltage Vcnv to the switched-capacitor circuit 20. The output terminal T102 is connected to an input terminal T200 of the switched-capacitor circuit 20 outside the pre-regulator circuit 10 and is connected to the switch S103 inside the pre-regulator circuit 10.

The power inductor L101 is an inductor used to boost and buck the DC voltage Vbat. One end of the power inductor L101 is connected to the switches S101 and S102, and the other end of the power inductor L101 is connected to the switches S103 and S104.

The switch S101 is connected between the input terminal T101 and the one end of the power inductor L101. The switch S102 is connected between the one end of the power inductor L101 and ground. In this connection configuration, exclusive switching between opening and closing of the switches S101 and S102 enables the DC voltage Vbat to be bucked.

The switch S103 is connected between the other end of the power inductor L101 and the output terminal T102. The switch S104 is connected between the other end of the power inductor L101 and ground. In this connection configuration, exclusive switching between opening and closing of the switches S103 and S104 enables the DC voltage Vbat to be boosted.

The capacitor C101 is connected between ground and a path between the switch S103 and the output terminal T102. In some examples, one of the two electrodes of the capacitor C101 is connected to the switch S103 and the output terminal T102, and the other of the two electrodes of the capacitor C101 is connected to ground.

The configuration of the pre-regulator circuit 10 illustrated in FIG. 3 is illustrative and is not restrictive. For example, one or some of the switches S101 to S104 may be replaced with a diode. A part or the entirety of the pre-regulator circuit 10 does not necessarily have to be included in the tracker circuit 1.

### 1.2.2 Circuit configuration of switched-capacitor circuit 20

Next, the circuit configuration of the switched-capacitor circuit 20 will be described with reference to FIG. 3. The switched-capacitor circuit 20 has a ladder circuit configuration and is configured to generate multiple discrete voltages V1, V2, V3, V4, V5, and V6, or V2, V3, V4, V5, and V6. In some examples, the switched-capacitor circuit 20 includes flying capacitors C200 to C209, smoothing capacitors C210 to C215, switches S200 to S225, the input terminal T200, and output terminals T201 to T206. Energy and electric charge are input from the pre-regulator circuit 10 to a node N5 via the input terminal T200, and are withdrawn from nodes N1, N2, N3, N4, N5, and N6 to the supply modulator 30 via the output terminals T201, T202, T203, T204, T205, and T206.

The input terminal T200 is a terminal for receiving the regulated voltage Vcnv from the pre-regulator circuit 10. The input terminal T200 is connected to the pre-regulator circuit 10 outside the switched-capacitor circuit 20 and is connected to the node N5 inside the switched-capacitor circuit 20. The node to which the input terminal T200 is connected is not limited to the node N5. The input terminal T200 may be connected to any of the nodes N1, N2, N3, N4, N5, and N6.

The output terminals T201, T202, T203, T204, T205, and T206 are terminals for supplying the multiple discrete voltages V1, V2, V3, V4, V5, and V6, respectively, to the supply modulator 30. The output terminals T201, T202, T203, T204, T205, and T206 are connected to the supply modulator 30 outside the switched-capacitor circuit 20 and are connected to the nodes N1, N2, N3, N4, N5, and N6, respectively, inside the switched-capacitor circuit 20.

The flying capacitors C200, C201, C202, C203, C204, C205, C206, C207, C208, and C209 may be referred to as transfer capacitors, and are used to boost and/or buck the regulated voltage Vcnv supplied from the pre-regulator circuit 10. In some examples, in the first mode, the flying capacitors C200, C201, C202, C203, C204, C205, C206, C207, C208, and C209 cause electric charge to be moved between a set of the flying capacitors C200, C201, C202, C203, C204, C205, C206, C207, C208, and C209 and a set of the nodes N1, N2, N3, N4, N5, and N6 and ground so that the voltages V1, V2, V3, V4, V5, and V6 satisfying (V6 - V5):(V5 - V4):(V4 - V3):(V3 - V2):(V2 - V1):(V1 - VG) = 1:1:1:1:1:1 and V6 > V5 > V4 > V3 > V2 > V1 > VG are maintained at the six nodes N1, N2, N3, N4, N5, and N6. Also, in the second mode, the flying capacitors C202, C203, C204, C205, C206, C207, C208, and C209 cause electric charge to be moved between a set of the flying capacitors C202, C203, C204, C205, C206, C207, C208, and C209 and a set of the nodes N2, N3, N4, N5, and N6 and ground so that the voltages V2, V3, V4, V5, and V6 satisfying (V6 - V5):(V5 - V4):(V4 - V3):(V3 - V2):(V2 - VG) = 1:1:1:1:1 and V6 > V5 > V4 > V3 > V2 > VG are maintained at the five nodes N2, N3, N4, N5, and N6. Here, VG represents the ground potential. Note that (V6 - V5):(V5 - V4):(V4 - V3):(V3 - V2):(V2 - V1):(V1 - VG) is not limited to 1:1:1:1:1:1 and can be designed to have any ratio (for example, 1:2:3:4:5:6).

The flying capacitor C200 is an example of a first flying capacitor. One of the two electrodes of the flying capacitor C200 is connected to one end of the switch S200 and one end of the switch S201. The other of the two electrodes of the flying capacitor C200 is switchably connected to one end of the switch S204 and one end of the switch S205 via the switch S224.

The flying capacitor C201 is an example of a second flying capacitor. One of the two electrodes of the flying capacitor C201 is connected to one end of the switch S202 and one end of the switch S203. The other of the two electrodes of the flying capacitor C201 is switchably connected to one end of the switch S206 and one end of the switch S207 via the switch S225.

The flying capacitor C202 is an example of a third flying capacitor. One of the two electrodes of the flying capacitor C202 is connected to the one end of the switch S204 and the one end of the switch S205. The other of the two electrodes of the flying capacitor C202 is connected to one end of the switch S208 and one end of the switch S209.

The flying capacitor C203 is an example of a fourth flying capacitor. One of the two electrodes of the flying capacitor C203 is connected to the one end of the switch S206 and the one end of the switch S207. The other of the two electrodes of the flying capacitor C203 is connected to one end of the switch S210 and one end of the switch S211.

The flying capacitor C204 is an example of a fifth flying capacitor. One of the two electrodes of the flying capacitor C204 is connected to the one end of the switch S208 and the one end of the switch S209. The other of the two electrodes of the flying capacitor C204 is connected to one end of the switch S212 and one end of the switch S213.

The flying capacitor C205 is an example of a sixth flying capacitor. One of the two electrodes of the flying capacitor C205 is connected to the one end of the switch S210 and the one end of the switch S211. The other of the two electrodes of the flying capacitor C205 is connected to one end of the switch S214 and one end of the switch S215.

One of the two electrodes of the flying capacitor C206 is connected to the one end of the switch S212 and the one end of the switch S213. The other of the two electrodes of the flying capacitor C206 is connected to one end of the switch S216 and one end of the switch S217.

One of the two electrodes of the flying capacitor C207 is connected to the one end of the switch S214 and the one end of the switch S215. The other of the two electrodes of the flying capacitor C207 is connected to one end of the switch S218 and one end of the switch S219.

One of the two electrodes of the flying capacitor C208 is connected to the one end of the switch S216 and the one end of the switch S217. The other of the two electrodes of the flying capacitor C208 is connected to one end of the switch S220 and one end of the switch S221.

One of the two electrodes of the flying capacitor C209 is connected to the one end of the switch S218 and the one end of the switch S219. The other of the two electrodes of the flying capacitor C209 is connected to one end of the switch S222 and one end of the switch S223.

The smoothing capacitors C210, C211, C212, C213, C214, and C215 are smoothing capacitors and are used to hold and smooth the discrete voltages V1, V2, V3, V4, V5, and V6 at the nodes N1, N2, N3, N4, N5, and N6.

The smoothing capacitor C210 is an example of a first smoothing capacitor and is connected between the node N1 and ground. In some examples, one of the two electrodes of the smoothing capacitor C210 is connected to the node N1. On the other hand, the other of the two electrodes of the smoothing capacitor C210 is connected to ground.

The smoothing capacitor C211 is an example of a second smoothing capacitor and is connected between the nodes N1 and N2. In some examples, one of the two electrodes of the smoothing capacitor C211 is connected to the node N2. On the other hand, the other of the two electrodes of the smoothing capacitor C211 is connected to the node N1.

The smoothing capacitor C212 is an example of a third smoothing capacitor and is connected between the nodes N2 and N3. In some examples, one of the two electrodes of the smoothing capacitor C212 is connected to the node N3. On the other hand, the other of the two electrodes of the smoothing capacitor C212 is connected to the node N2.

The smoothing capacitor C213 is an example of a fourth smoothing capacitor and is connected between the nodes N3 and N4. In some examples, one of the two electrodes of the smoothing capacitor C213 is connected to the node N4. On the other hand, the other of the two electrodes of the smoothing capacitor C213 is connected to the node N3.

The smoothing capacitor C214 is connected between the nodes N4 and N5. In some examples, one of the two electrodes of the smoothing capacitor C214 is connected to the node N5. On the other hand, the other of the two electrodes of the smoothing capacitor C214 is connected to the node N4.

The smoothing capacitor C215 is connected between the nodes N5 and N6. In some examples, one of the two electrodes of the smoothing capacitor C215 is connected to the node N6. On the other hand, the other of the two electrodes of the smoothing capacitor C215 is connected to the node N5.

The switch S200 is an example of a first switch and is connected between the flying capacitor C200 and ground. In some examples, the one end of the switch S200 is connected to the one of the two electrodes of the flying capacitor C200. On the other hand, the other end of the switch S200 is connected to ground.

The switch S201 is an example of a second switch and is connected between the flying capacitor C200 and the node N1. In some examples, the one end of the switch S201 is connected to the one of the two electrodes of the flying capacitor C200. On the other hand, the other end of the switch S201 is connected to the node N1.

The switch S202 is an example of a third switch and is connected between the flying capacitor C201 and ground. In some examples, the one end of the switch S202 is connected to the one of the two electrodes of the flying capacitor C201. On the other hand, the other end of the switch S202 is connected to ground.

The switch S203 is an example of a fourth switch and is connected between the flying capacitor C201 and the node N1. In some examples, the one end of the switch S203 is connected to the one of the two electrodes of the flying capacitor C201. On the other hand, the other end of the switch S203 is connected to the node N1.

The switch S204 is an example of a fifth switch and is connected between the flying capacitors C200 and C202 and the node N1. In some examples, the one end of the switch S204 is switchably connected to the other of the two electrodes of the flying capacitor C200 via the switch S224, and is also connected to the one of the two electrodes of the flying capacitor C202. On the other hand, the other end of the switch S204 is connected to the node N1.

The switch S205 is an example of a sixth switch and is connected between the flying capacitors C200 and C202 and the node N2. In some examples, the one end of the switch S205 is switchably connected to the other of the two electrodes of the flying capacitor C200 via the switch S224, and is also connected to the one of the two electrodes of the flying capacitor C202. On the other hand, the other end of the switch S205 is connected to the node N2.

The switch S206 is an example of a seventh switch and is connected between the flying capacitors C201 and C203 and the node N1. In some examples, the one end of the switch S206 is switchably connected to the other of the two electrodes of the flying capacitor C201 via the switch S225, and is also connected to the one of the two electrodes of the flying capacitor C203. On the other hand, the other end of the switch S206 is connected to the node N1.

The switch S207 is an example of an eighth switch and is connected between the flying capacitors C201 and C203 and the node N2. In some examples, the one end of the switch S207 is switchably connected to the other of the two electrodes of the flying capacitor C201 via the switch S225, and is also connected to the one of the two electrodes of the flying capacitor C203. On the other hand, the other end of the switch S207 is connected to the node N2.

The switch S208 is an example of a ninth switch and is connected between the flying capacitors C202 and C204 and the node N2. In some examples, the one end of the switch S208 is connected to the other of the two electrodes of the flying capacitor C202 and the one of the two electrodes of the flying capacitor C204. On the other hand, the other end of the switch S208 is connected to the node N2.

The switch S209 is an example of a tenth switch and is connected between the flying capacitors C202 and C204 and the node N3. In some examples, the one end of the switch S209 is connected to the other of the two electrodes of the flying capacitor C202 and the one of the two electrodes of the flying capacitor C204. On the other hand, the other end of the switch S209 is connected to the node N3.

The switch S210 is an example of an eleventh switch and is connected between the flying capacitors C203 and C205 and the node N2. In some examples, the one end of the switch S210 is connected to the other of the two electrodes of the flying capacitor C203 and the one of the two electrodes of the flying capacitor C205. On the other hand, the other end of the switch S210 is connected to the node N2.

The switch S211 is an example of a twelfth switch and is connected between the flying capacitors C203 and C205 and the node N3. In some examples, the one end of the switch S211 is connected to the other of the two electrodes of the flying capacitor C203 and the one of the two electrodes of the flying capacitor C205. On the other hand, the other end of the switch S211 is connected to the node N3.

The switch S212 is an example of a fifteenth switch and is connected between the flying capacitors C204 and C206 and the node N3. In some examples, the one end of the switch S212 is connected to the other of the two electrodes of the flying capacitor C204 and the one of the two electrodes of the flying capacitor C206. On the other hand, the other end of the switch S212 is connected to the node N3.

The switch S213 is an example of a sixteenth switch and is connected between the flying capacitors C204 and C206 and the node N4. In some examples, the one end of the switch S213 is connected to the other of the two electrodes of the flying capacitor C204 and the one of the two electrodes of the flying capacitor C206. On the other hand, the other end of the switch S213 is connected to the node N4.

The switch S214 is an example of a seventeenth switch and is connected between the flying capacitors C205 and C207 and the node N3. In some examples, the one end of the switch S214 is connected to the other of the two electrodes of the flying capacitor C205 and the one of the two electrodes of the flying capacitor C207. On the other hand, the other end of the switch S214 is connected to the node N3.

The switch S215 is an example of an eighteenth switch and is connected between the flying capacitors C205 and C207 and the node N4. In some examples, the one end of the switch S215 is connected to the other of the two electrodes of the flying capacitor C205 and the one of the two electrodes of the flying capacitor C207. On the other hand, the other end of the switch S215 is connected to the node N4.

The switch S216 is connected between the flying capacitors C206 and C208 and the node N4. In some examples, the one end of the switch S216 is connected to the other of the two electrodes of the flying capacitor C206 and the one of the two electrodes of the flying capacitor C208. On the other hand, the other end of the switch S216 is connected to the node N4.

The switch S217 is connected between the flying capacitors C206 and C208 and the node N5. In some examples, the one end of the switch S217 is connected to the other of the two electrodes of the flying capacitor C206 and the one of the two electrodes of the flying capacitor C208. On the other hand, the other end of the switch S217 is connected to the node N5.

The switch S218 is connected between the flying capacitors C207 and C209 and the node N4. In some examples, the one end of the switch S218 is connected to the other of the two electrodes of the flying capacitor C207 and the one of the two electrodes of the flying capacitor C209. On the other hand, the other end of the switch S218 is connected to the node N4.

The switch S219 is connected between the flying capacitors C207 and C209 and the node N5. In some examples, the one end of the switch S219 is connected to the other of the two electrodes of the flying capacitor C207 and the one of the two electrodes of the flying capacitor C209. On the other hand, the other end of the switch S219 is connected to the node N5.

The switch S220 is connected between the flying capacitor C208 and the node N5. In some examples, the one end of the switch S220 is connected to the other of the two electrodes of the flying capacitor C208. On the other hand, the other end of the switch S220 is connected to the node N5.

The switch S221 is connected between the flying capacitor C208 and the node N6. In some examples, the one end of the switch S221 is connected to the other of the two electrodes of the flying capacitor C208. On the other hand, the other end of the switch S221 is connected to the node N6.

The switch S222 is connected between the flying capacitor C209 and the node N5. In some examples, the one end of the switch S222 is connected to the other of the two electrodes of the flying capacitor C209. On the other hand, the other end of the switch S222 is connected to the node N5.

The switch S223 is connected between the flying capacitor C209 and the node N6. In some examples, the one end of the switch S223 is connected to the other of the two electrodes of the flying capacitor C209. On the other hand, the other end of the switch S223 is connected to the node N6.

The switch S224 is an example of a thirteenth switch and is connected between the flying capacitor C200 and a set of the flying capacitor C202 and the switches S204 and S205. In some examples, one end of the switch S224 is connected to the other of the two electrodes of the flying capacitor C200. On the other hand, the other end of the switch S224 is connected to the one of the two electrodes of the flying capacitor C202, the one end of the switch S204, and the one end of the switch S205. Opening the switch S224 causes the flying capacitor C200 to be disconnected from the flying capacitor C202.

The switch S225 is an example of a fourteenth switch and is connected between the flying capacitor C201 and a set of the flying capacitor C203 and the switches S206 and S207. In some examples, one end of the switch S225 is connected to the other of the two electrodes of the flying capacitor C201. On the other hand, the other end of the switch S225 is connected to the one of the two electrodes of the flying capacitor C203, the one end of the switch S206, and the one end of the switch S207. Opening the switch S225 causes the flying capacitor C201 to be disconnected from the flying capacitor C203.

### 1.2.3 Circuit configuration of supply modulator 30

Next, the circuit configuration of the supply modulator 30 will be described with reference to FIG. 3. The supply modulator 30 includes input terminals T301 to T306, an output terminal T307, and switches S301 to S306.

The input terminals T301, T302, T303, T304, T305, and T306 are terminals for receiving the multiple discrete voltages V1, V2, V3, V4, V5, and V6 generated by the switched-capacitor circuit 20, respectively. The input terminals T301, T302, T303, T304, T305, and T306 are respectively connected to the output terminals T201, T202, T203, T204, T205, and T206 of the switched-capacitor circuit 20 outside the supply modulator 30, and are respectively connected to the switches S301, S302, S303, S304, S305, and S306 inside the supply modulator 30.

The output terminal T307 is a terminal for selectively supplying at least one of the multiple discrete voltages V1, V2, V3, V4, V5, and V6 to the power amplifier 2. The output terminal T307 is connected to the output terminal 42 outside the supply modulator 30, and is connected to the switches S301, S302, S303, S304, S305, and S306 inside the supply modulator 30.

The switch S301 is connected between the input terminal T301 and the output terminal T307. The switch S302 is connected between the input terminal T302 and the output terminal T307. The switch S303 is connected between the input terminal T303 and the output terminal T307. The switch S304 is connected between the input terminal T304 and the output terminal T307. The switch S305 is connected between the input terminal T305 and the output terminal T307. The switch S306 is connected between the input terminal T306 and the output terminal T307.

These switches S301, S302, S303, S304, S305, and S306 are opened or closed (turned ON or OFF) in response to the control signal CS30 from the digital control circuit 60. In the present exemplary embodiment, the switches S301, S302, S303, S304, S305, and S306 are controlled so as to be exclusively turned ON. In other words, control is performed such that only any one of the switches S301, S302, S303, S304, S305, and S306 is closed and all the other switches are opened. Accordingly, the supply modulator 30 is configured to supply one voltage selected from among the multiple discrete voltages V1, V2, V3, V4, V5, and V6 to the power amplifier 2.

The configuration of the supply modulator 30 illustrated in FIG. 3 is illustrative and is not restrictive. In particular, the switches S301, S302, S303, S304, S305, and S306 may have any configuration and may be controlled in any manner as long as at least one of the six input terminals T301, T302, T303, T304, T305, and T306 can be selectively connected to the output terminal T307. For example, two of the switches S301, S302, S303, S304, S305, and S306 may be closed, and the remaining four of the switches S301, S302, S303, S304, S305, and S306 may be opened.

### 1.2.4 Circuit configuration of digital control circuit 60

Next, the circuit configuration of the digital control circuit 60 will be described with reference to FIG. 3. The digital control circuit 60 includes a first controller 61 and a second controller 62.

The first controller 61 is configured to process serial data signals (CLK and DATA) supplied from the RFIC 5 to generate the control signals CS10 and CS20 for controlling the pre-regulator circuit 10 and the switched-capacitor circuit 20. The control signal CS10 is a signal for controlling opening and closing of the switches S101 to S104 included in the pre-regulator circuit 10. The control signal CS20 is a signal for controlling opening and closing of the switches S200 to S225 included in the switched-capacitor circuit 20. The first controller 61 may receive a feedback signal for controlling the pre-regulator circuit 10.

The serial data signals may be, for example, source-synchronous digital control signals. Alternatively, the serial data signals may be clock-embedded digital control signals. The first controller 61 may generate a control signal for controlling the supply modulator 30.

In the present exemplary embodiment, the pre-regulator circuit 10 and the switched-capacitor circuit 20 share one set of a clock signal (CLK) and a data signal (DATA), but the exemplary embodiment is not limited thereto. For example, the pre-regulator circuit 10 and the switched-capacitor circuit 20 may each use one set of a clock signal and a data signal.

The second controller 62 is configured to process parallel data signals supplied from the RFIC 5 to generate the control signal CS30 for controlling the supply modulator 30. The parallel data signals may be, for example, digital control level (DCL) signals (DCL1, DCL2, and DCL3). The DCL signals (DCL1, DCL2, and DCL3) are generated based on an envelope signal of an RF signal by the RFIC 5. The control signal CS30 is a signal for controlling opening and closing of the switches S301, S302, S303, S304, S305, and S306 included in the supply modulator 30.

The DCL signals (DCL1, DCL2, and DCL3) are each a 1-bit signal. The multiple discrete voltages V1, V2, V3, V4, V5, and V6 are each represented by a combination of two 1-bit signals. For example, V1, V2, V3, V4, V5, and V6 are represented by "000", "001", "010", "011", "110", and "111", respectively. A gray code may be used to express a voltage level.

Although three DCL signals are used to control the supply modulator 30 in the present exemplary embodiment, the number of DCL signals is not limited thereto. For example, one DCL signal, two DCL signals, or any number of four or more DCL signals may be used in accordance with the number of voltage levels selectable by the supply modulator 30. The parallel data signals used to control the supply modulator 30 are not limited to DCL signals.

### 1.3 Method for controlling switched-capacitor circuit 20

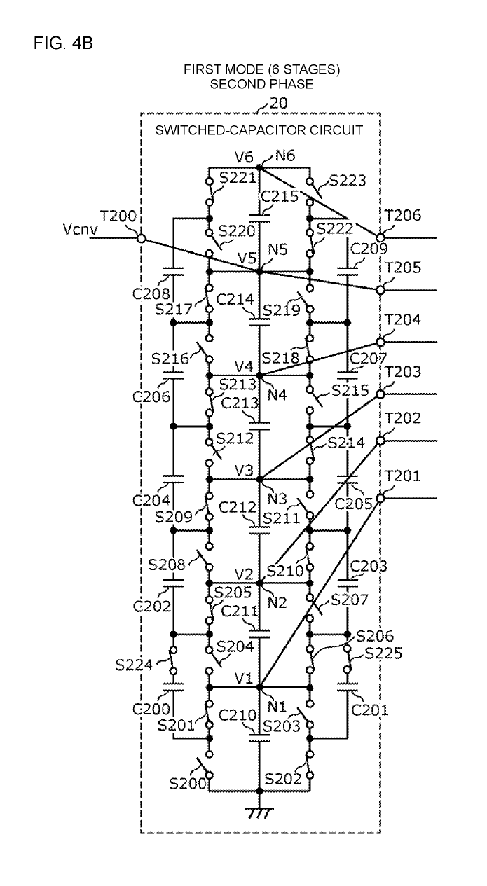

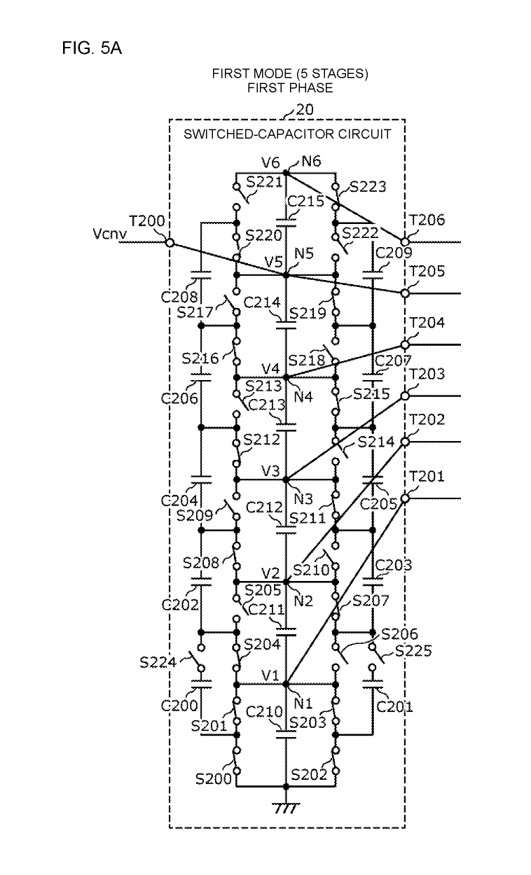

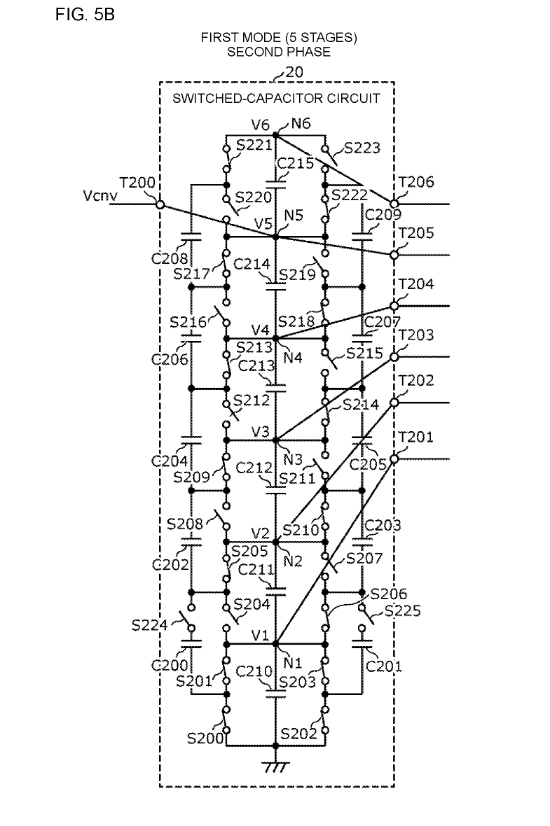

Next, a method for controlling the switched-capacitor circuit 20 according to the present exemplary embodiment will be described with reference to FIG. 4A, FIG. 4B, FIG. 5A, and FIG. 5B.

### 1.3.1 First mode

First, the first mode will be described with reference to FIG. 4A and FIG. 4B. FIG. 4A is a circuit configuration diagram illustrating a connection state in a first phase of the first mode of the switched-capacitor circuit 20 according to the present exemplary embodiment. FIG. 4B is a circuit configuration diagram illustrating a connection state in a second phase of the first mode of the switched-capacitor circuit 20 according to the present exemplary embodiment.

The first mode is a mode in which the switched-capacitor circuit 20 generates six discrete voltages V1, V2, V3, V4, V5, and V6. That is, in the first mode, the switched-capacitor circuit 20 operates as a six-stage switched-capacitor.

In the first mode, the first phase and the second phase are alternately repeated based on the control signal CS20 from the digital control circuit 60.

In the first phase of the first mode, as illustrated in FIG. 4A, the switches S200, S203, S204, S207, S208, S211, S212, S215, S216, S219, S220, and S223 included in a first set are closed, whereas the switches S201, S202, S205, S206, S209, S210, S213, S214, S217, S218, S221, and S222 included in a second set are opened. Furthermore, the switches S224 and S225 are closed.

In the second phase of the first mode, as illustrated in FIG. 4B, the switches S200, S203, S204, S207, S208, S211, S212, S215, S216, S219, S220, and S223 included in the first set are opened, whereas the switches S201, S202, S205, S206, S209, S210, S213, S214, S217, S218, S221, and S222 included in the second set are closed. Furthermore, the switches S224 and S225 are closed.

In this way, in the first mode, the first set of switches and the second set of switches are alternately opened and closed in the first phase and the second phase. On the other hand, the switches S224 and S225 are kept closed in the first phase and the second phase.

As a result of the first phase and the second phase being repeated, the flying capacitors C200, C201, C202, C203, C204, C205, C206, C207, C208, and C209 are configured to perform charging and discharging in a complementary manner. For example, in one of the first phase and the second phase, charging from the flying capacitors C200, C202, C204, C206, and C208 to the smoothing capacitors C210, C211, C212, C213, C214, and C215 is performed. In the other of the first phase and the second phase, charging from the flying capacitors C201, C203, C205, C207, and C209 to the smoothing capacitors C210, C211, C212, C213, C214, and C215 is performed. That is, the smoothing capacitors C210, C211, C212, C213, C214, and C215 are constantly charged from any of the flying capacitors C200, C201, C202, C203, C204, C205, C206, C207, C208, and C209. Thus, even when a current rapidly flows from any of the nodes N1, N2, N3, N4, N5, and N6 to the supply modulator 30, electric charge is rapidly replenished at any of the nodes N1, N2, N3, N4, N5, and N6, and potential variations at the nodes N1, N2, N3, N4, N5, and N6 can be reduced.

As a result of operating in the above-described manner, the switched-capacitor circuit 20 is configured to maintain substantially equal voltages across each of the smoothing capacitors C210, C211, C212, C213, C214, and C215. In some examples, at the six nodes N1, N2, N3, N4, N5, and N6 labeled V1, V2, V3, V4, V5, and V6, respectively, the multiple discrete voltages V1, V2, V3, V4, V5, and V6 satisfying (V6 - V5):(V5 - V4):(V4 - V3):(V3 - V2):(V2 - V1):(V1 - VG) = 1:1:1:1:1:1 are maintained. For example, when the regulated voltage Vcnv supplied from the pre-regulator circuit 10 is 5 V, the switched-capacitor circuit 20 is configured to generate 1 V, 2 V, 3 V, 4 V, 5 V, and 6 V as the six discrete voltages V1, V2, V3, V4, V5, and V6.

### 1.3.2 Second mode

Next, the second mode will be described with reference to FIG. 5A and FIG. 5B. FIG. 5A is a circuit configuration diagram illustrating a connection state in a first phase of the second mode of the switched-capacitor circuit 20 according to the present exemplary embodiment. FIG. 5B is a circuit configuration diagram illustrating a connection state in a second phase of the second mode of the switched-capacitor circuit 20 according to the present exemplary embodiment.

The second mode is a mode in which the switched-capacitor circuit 20 generates five discrete voltages V2, V3, V4, V5, and V6. That is, in the second mode, the switched-capacitor circuit 20 operates as a five-stage switched-capacitor.

In the second mode, the first phase and the second phase are alternately repeated based on the control signal CS20 from the digital control circuit 60.

In the first phase of the second mode, as illustrated in FIG. 5A, the switches S204, S207, S208, S211, S212, S215, S216, S219, S220, and S223 included in a third set are closed, whereas the switches S205, S206, S209, S210, S213, S214, S217, S218, S221, and S222 included in a fourth set are opened. Furthermore, the switches S200, S201, S202, and S203 are closed, whereas the switches S224 and S225 are opened.

In the second phase of the second mode, as illustrated in FIG. 5B, the switches S204, S207, S208, S211, S212, S215, S216, S219, S220, and S223 included in the third set are opened, whereas the switches S205, S206, S209, S210, S213, S214, S217, S218, S221, and S222 included in the fourth set are closed. Furthermore, the switches S200, S201, S202, and S203 are closed, whereas the switches S224 and S225 are opened.

In this way, in the second mode, the third set of switches and the fourth set of switches are alternately opened and closed in the first phase and the second phase. On the other hand, the switches S200, S201, S202, and S203 are kept closed in the first phase and the second phase, whereas the switches S224 and S225 are kept open in the first phase and the second phase.

As a result of the first phase and the second phase being repeated, the flying capacitors C202, C203, C204, C205, C206, C207, C208, and C209 are configured to perform charging and discharging in a complementary manner. For example, in one of the first phase and the second phase, charging from the flying capacitors C202, C204, C206, and C208 to the smoothing capacitors C211, C212, C213, C214, and C215 is performed. In the other of the first phase and the second phase, charging from the flying capacitors C203, C205, C207, and C209 to the smoothing capacitors C211, C212, C213, C214, and C215 is performed. That is, the smoothing capacitors C211, C212, C213, C214, and C215 are constantly charged from any of the flying capacitors C202, C203, C204, C205, C206, C207, C208, and C209. Thus, even when a current rapidly flows from any of the nodes N2, N3, N4, N5, and N6 to the supply modulator 30, electric charge is rapidly replenished at any of the nodes N2, N3, N4, N5, and N6, and potential variations at the nodes N2, N3, N4, N5, and N6 can be reduced.

As a result of operating in the above-described manner, the switched-capacitor circuit 20 is configured to maintain substantially equal voltages across each of the smoothing capacitors C211, C212, C213, C214, and C215. In some examples, at the five nodes N2, N3, N4, N5, and N6 labeled V2, V3, V4, V5, and V6, respectively, the multiple discrete voltages V2, V3, V4, V5, and V6 satisfying (V6 - V5):(V5 - V4):(V4 - V3):(V3 - V2):(V2 - VG) = 1:1:1:1:1 are maintained. For example, when the regulated voltage Vcnv supplied from the pre-regulator circuit 10 is 5 V, the switched-capacitor circuit 20 is configured to generate 1.25 V, 2.5 V, 3.75 V, 5 V, and 6.25 V as the five discrete voltages V2, V3, V4, V5, and V6 in the second mode.

### 1.4 Multiple discrete voltages generated in first mode and second mode

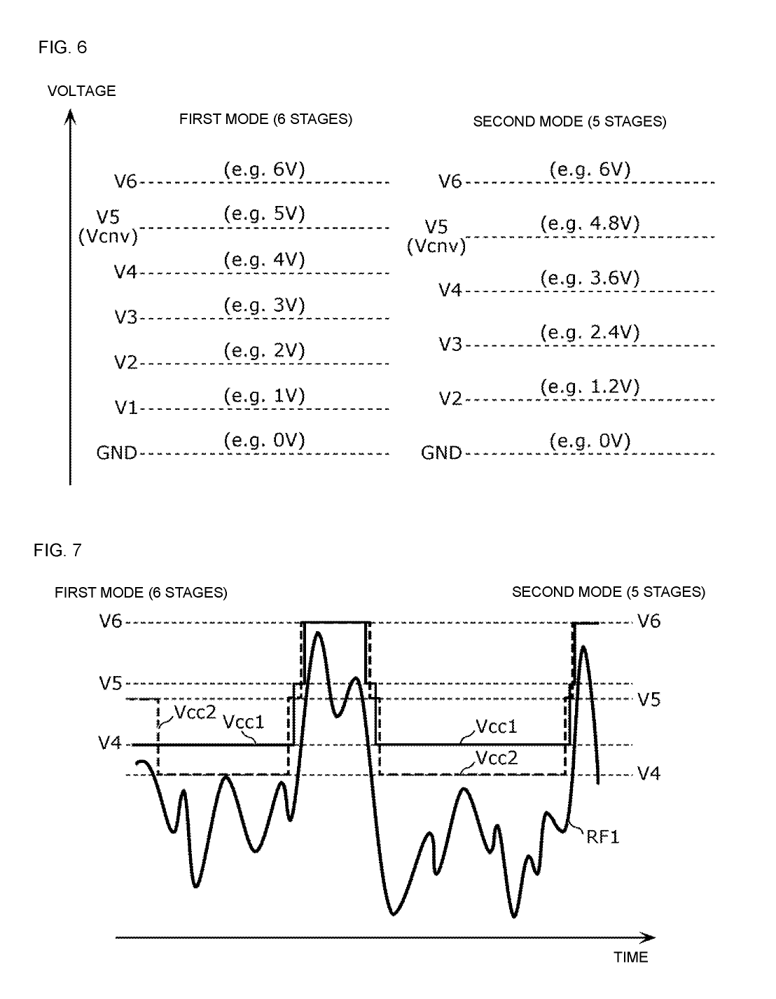

Next, multiple discrete voltages generated by the switched-capacitor circuit 20 according to the present exemplary embodiment will be described with reference to FIG. 6. FIG. 6 is a diagram illustrating an example of multiple discrete voltages generated by the switched-capacitor circuit 20 according to the present exemplary embodiment. In FIG. 6, the power supply voltage Vcc corresponding to the peak power of the RF signal amplified by the power amplifier 2 is 6 V.

For example, in the first mode, a regulated voltage Vcnv of 5 V is supplied from the pre-regulator circuit 10 to the switched-capacitor circuit 20. In this case, the switched-capacitor circuit 20 is configured to generate six discrete voltages of 1 V, 2 V, 3 V, 4 V, 5 V, and 6 V.

For example, in the second mode, a regulated voltage Vcnv of 4.8 V is supplied from the pre-regulator circuit 10 to the switched-capacitor circuit 20. In this case, the switched-capacitor circuit 20 is configured to generate five discrete voltages of 1.2 V, 2.4 V, 3.6 V, 4.8 V, and 6 V.

### 1.5 Power supply voltages supplied to power amplifier 2

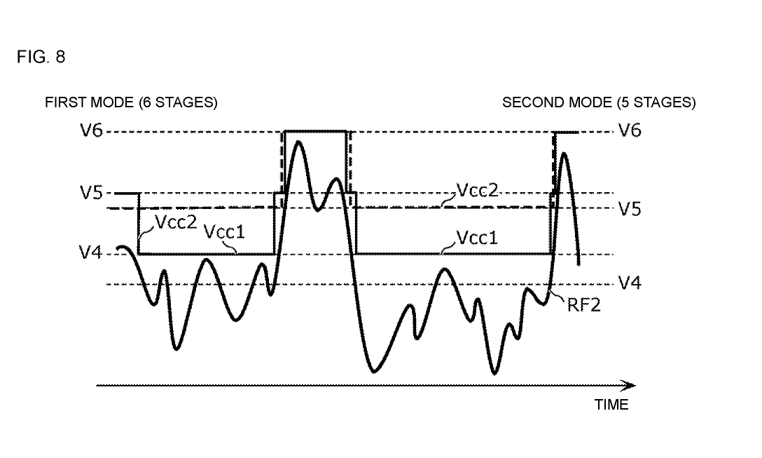

Now, power supply voltages Vcc1 and Vcc2 supplied to the power amplifier 2 in the first mode and second mode will be described with reference to FIG. 7 and FIG. 8.

### 1.5.1 Power supply voltage for first RF signal having higher PAPR

First, the power supply voltage Vcc supplied to amplify a first RF signal having a PAPR higher than or equal to a threshold will be described with reference to FIG. 7. FIG. 7 is a graph illustrating an example of temporal changes in the power supply voltages Vcc1 and Vcc2 that can be supplied to the power amplifier 2 by the tracker circuit 1 according to the present exemplary embodiment. In FIG. 7, the horizontal axis represents time. The solid line represents the power supply voltage Vcc1 that can be supplied in the first mode, and the broken line represents the power supply voltage Vcc2 that can be supplied in the second mode. An envelope signal RF1 represents the envelope signal of the first RF signal.

Referring to FIG. 7, in both the first mode and the second mode, three discrete voltages V4, V5, and V6 that are higher than a predetermined voltage (for example, the power supply voltage corresponding to the average power of the first RF signal) can be used as the power supply voltages Vcc1 and Vcc2, from among the multiple discrete voltages. In such a case, the power supply voltage Vcc2 that can be supplied in the second mode can track the envelope signal RF1 of the first RF signal down to a lower voltage than the power supply voltage Vcc1 that can be supplied in the first mode. Thus, in FIG. 7, the second mode can implement higher power efficiency than the first mode. That is, the power efficiency can be improved by applying the second mode to the switched-capacitor circuit 20 when the PAPR of the RF signal amplified by the power amplifier 2 is higher than or equal to the threshold.

The threshold used here may be a value that is empirically and/or experimentally predetermined. The PAPR of the RF signal can be measured by using an RF power detector.

### 1.5.2 Power supply voltage for second RF signal having lower PAPR

Next, the power supply voltage Vcc supplied to amplify a second RF signal having a PAPR lower than the threshold will be described with reference to FIG. 8. FIG. 8 is a graph illustrating an example of temporal changes in the power supply voltages Vcc1 and Vcc2 that can be supplied to the power amplifier 2 by the tracker circuit 1 according to the present exemplary embodiment. In FIG. 8, the horizontal axis represents time. The solid line represents the power supply voltage Vcc1 that can be supplied in the first mode, and the broken line represents the power supply voltage Vcc2 that can be supplied in the second mode. An envelope signal RF2 represents the envelope signal of the second RF signal.

Referring to FIG. 8, in the first mode, three discrete voltages V4, V5, and V6 that are higher than a predetermined voltage (for example, the power supply voltage corresponding to the average power of the second RF signal) are used from among the multiple discrete voltages V1, V2, V3, V4, V5, and V6. On the other hand, in the second mode, two discrete voltages V5 and V6 that are higher than the predetermined voltage are used from among the multiple discrete voltages V2, V3, V4, V5, and V6.

In such a case, the power supply voltage Vcc1 that can be supplied in the first mode can track the envelope signal RF2 of the second RF signal down to a lower voltage than the power supply voltage Vcc2 that can be supplied in the second mode. Thus, in FIG. 8, the first mode can implement higher power efficiency than the second mode. That is, the power efficiency can be improved by applying the first mode to the switched-capacitor circuit 20 when the PAPR of the RF signal amplified by the power amplifier 2 is lower than the threshold.

FIG. 7 and FIG. 8 illustrate exemplary embodiments and are not intended to limit the combination of discrete voltages that can be supplied to the power amplifier 2 in the first mode and the second mode. FIG. 7 and FIG. 8 illustrate the period during which three discrete voltages V4, V5, and V6 of the multiple discrete voltages are supplied. However, during other periods, the other discrete voltages V1, V2, and V3 may be supplied. That is, the combination of discrete voltages supplied to the power amplifier 2 is not limited to the examples illustrated in FIG. 7 and FIG. 8.

The relationship between the PAPR and the first and second modes is not limited to the above. For example, when the PAPR is higher than or equal to the threshold, the first mode configured to generate more discrete voltages may be applied to the switched-capacitor circuit 20; and when the PAPR is lower than the threshold, the second mode configured to generate fewer discrete voltages may be applied to the switched-capacitor circuit 20.

Alternatively, for example, the mode may be switched between the first mode and the second mode in accordance with the modulation scheme for the RF signal. For example, when the bit rate of the modulation scheme for the RF signal is higher than or equal to a threshold, the second mode configured to generate fewer discrete voltages may be applied to the switched-capacitor circuit 20; and when the bit rate of the modulation scheme for the RF signal is lower than the threshold, the first mode configured to generate more discrete voltages may be applied to the switched-capacitor circuit 20. Conversely, when the bit rate of the modulation scheme for the RF signal is higher than or equal to the threshold, the first mode may be applied to the switched-capacitor circuit 20; and when the bit rate of the modulation scheme for the RF signal is lower than the threshold, the second mode may be applied to the switched-capacitor circuit 20.

The bit rate of the modulation scheme for the RF signal can be determined by measuring constellation points of the RF signal. The number of separable constellation points increases as the bit rate of the modulation scheme increases. In general, quadrature amplitude modulation (QAM) (for example, 256QAM, 64QAM, 16QAM, or the like) has a higher bit rate and a higher PAPR than phase shift keying (PSK) (for example, quadrature phase shift keying (QPSK), binary phase shift keying (BPSK), or the like).

### 1.6 Conclusion

As described above, the tracker circuit 1 according to the present exemplary embodiment includes the switched-capacitor circuit 20 configured to generate multiple discrete voltages from an input voltage; and the supply modulator 30 configured to selectively output, to the power amplifier 2, at least one of the multiple discrete voltages that have been generated. The switched-capacitor circuit 20 includes the flying capacitors C200, C201, C202, and C203; the smoothing capacitors C210, C211, and C212; and the switches S200, S201, S202, S203, S204, S205, S206, S207, S208, S209, S210, S211, S224, and S225. One end of the switch S200 and one end of the switch S201 are connected to one of the two electrodes of the flying capacitor C200. One end of the switch S202 and one end of the switch S203 are connected to one of the two electrodes of the flying capacitor C201. One end of the switch S204 and one end of the switch S205 are switchably connected to the other of the two electrodes of the flying capacitor C200 via the switch S224, and are connected to one of the two electrodes of the flying capacitor C202. One end of the switch S206 and one end of the switch S207 are switchably connected to the other of the two electrodes of the flying capacitor C201 via the switch S225, and are connected to one of the two electrodes of the flying capacitor C203. One end of the switch S208 and one end of the switch S209 are connected to the other of the two electrodes of the flying capacitor C202. One end of the switch S210 and one end of the switch S211 are connected to the other of the two electrodes of the flying capacitor C203. The other end of the switch S200, the other end of the switch S202, and one of the two electrodes of the smoothing capacitor C210 are connected to ground. The other end of the switch S201, the other end of the switch S203, the other end of the switch S204, and the other end of the switch S206 are connected to the other of the two electrodes of the smoothing capacitor C210 and one of the two electrodes of the smoothing capacitor C211. The other end of the switch S205, the other end of the switch S207, the other end of the switch S208, and the other end of the switch S210 are connected to the other of the two electrodes of the smoothing capacitor C211 and one of the two electrodes of the smoothing capacitor C212. The other end of the switch S209 and the other end of the switch S211 are connected to the other of the two electrodes of the smoothing capacitor C212. One end of the switch S224 is connected to the other of the two electrodes of the flying capacitor C200. The other end of the switch S224 is connected to the one of the two electrodes of the flying capacitor C202. One end of the switch S225 is connected to the other of the two electrodes of the flying capacitor C201. The other end of the switch S225 is connected to the one of the two electrodes of the flying capacitor C203.

Accordingly, the switch S224 is configured to disconnect the flying capacitors C200 and C202 from each other, and the switch S225 is configured to disconnect the flying capacitors C201 and C203 from each other. Thus, it is possible to switch the flying capacitors C200 and C201 between enabled and disabled states in the switched-capacitor circuit 20. As a result, it is possible to increase the range of variations of the number of multiple discrete voltages that can be generated by the switched-capacitor circuit 20. This makes it possible to generate multiple discrete voltages more suitable for the RF signal amplified by the power amplifier 2, thereby improving power efficiency in the D-ET mode.

For example, in the tracker circuit 1 according to the present exemplary embodiment, when the PAPR of the RF signal amplified by the power amplifier 2 is lower than a threshold, the switch S224 and the switch S225 may be kept closed; and when the PAPR is higher than or equal to the threshold, the switch S200, the switch S201, the switch S202, and the switch S203 may be kept closed, and the switch S224 and the switch S225 may be kept open.

Accordingly, it is possible to reduce the number of multiple discrete voltages when the PAPR of the RF signal amplified by the power amplifier 2 is high. The average power of an RF signal having a higher PAPR is lower than the average power of an RF signal having a lower PAPR when the RF signals have the same peak power. As illustrated in FIG. 7, when the number of voltages that can be supplied in the D-ET mode is limited, a smaller number of multiple discrete voltages makes it possible to track the envelope signal of the RF signal down to a lower voltage. Thus, as a result of reducing the number of multiple discrete voltages when the PAPR of the RF signal amplified by the power amplifier 2 is high, power efficiency can be improved in the D-ET mode.

The tracker circuit 1 according to the present exemplary embodiment includes the switched-capacitor circuit 20 having a first mode that generates multiple first discrete voltages from an input voltage and a second mode that generates multiple second discrete voltages from the input voltage; and the supply modulator 30 configured to selectively output, to the power amplifier 2, at least one of the multiple first discrete voltages that have been generated or at least one of the multiple second discrete voltages that have been generated. The number of the multiple first discrete voltages is greater than the number of the multiple second discrete voltages.

Accordingly, it is possible to switch the number of multiple discrete voltages generated by the switched-capacitor circuit 20. Thus, it is possible to generate multiple discrete voltages more suitable for the RF signal amplified by the power amplifier 2, thereby improving power efficiency in the D-ET mode.

### MODIFICATION OF FIRST EXEMPLARY EMBODIMENT

The switched-capacitor circuit 20 according to the first exemplary embodiment includes the switch S224 for disconnecting the flying capacitors C200 and C202 from each other and the switch S225 for disconnecting the flying capacitors C201 and C203 from each other. The switched-capacitor circuit may further include another switch for disconnecting two other flying capacitors from each other.

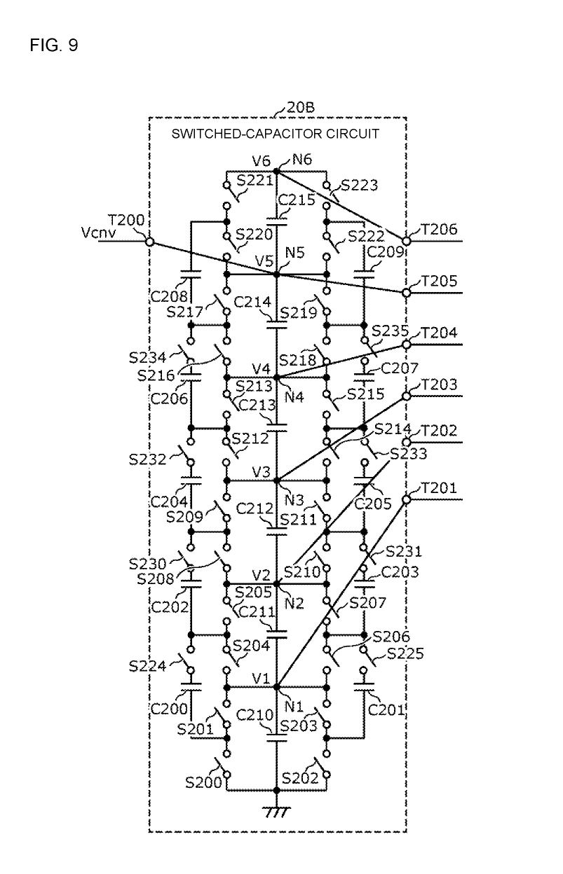

For example, as illustrated in FIG. 9, a switched-capacitor circuit 20B according to the present modification may include a switch S230 for disconnecting the flying capacitors C202 and C204 from each other and a switch S231 for disconnecting the flying capacitors C203 and C205 from each other. Here, the switches S230 and S231 are respective examples of a nineteenth switch and a twentieth switch.

In this case, the switched-capacitor circuit 20B is configured to implement a third mode that generates four discrete voltages V3, V4, V5, and V6, in addition to the above-described first and second modes.

In a first phase of the third mode, the switches S208, S211, S212, S215, S216, S219, S220, and S223 included in a fifth set are closed, whereas the switches S209, S210, S213, S214, S217, S218, S221, and S222 included in a sixth set are opened. Furthermore, the switches S200, S201, S202, S203, S204, S205, S206, and S207 are closed, whereas the switches S224, S225, S230, and S231 are opened.

In a second phase of the third mode, the switches S208, S211, S212, S215, S216, S219, S220, and S223 included in the fifth set are opened, whereas the switches S209, S210, S213, S214, S217, S218, S221, and S222 included in the sixth set are closed. Furthermore, the switches S200, S201, S202, S203, S204, S205, S206, and S207 are closed, whereas the switches S224, S225, S230, and S231 are opened.

In this way, in the third mode, the fifth set of switches and the sixth set of switches are alternately opened and closed in the first phase and the second phase. On the other hand, the switches S200, S201, S202, S203, S204, S205, S206, and S207 are kept closed in the first phase and the second phase, whereas the switches S224, S225, S230, and S231 are kept open in the first phase and the second phase.

Accordingly, the switched-capacitor circuit 20B is configured to maintain multiple discrete voltages V3, V4, V5, and V6 satisfying (V6 - V5):(V5 - V4):(V4 - V3):(V3 - VG) = 1:1:1:1 at the four nodes N3, N4, N5, and N6 labeled V3, V4, V5, and V6, respectively. For example, when the regulated voltage Vcnv supplied from the pre-regulator circuit 10 is 5 V, the switched-capacitor circuit 20B is configured to generate 1.67 V, 3.33 V, 5 V, and 6.67 V as the four discrete voltages V3, V4, V5, and V6 in the third mode.

As illustrated in FIG. 9, the switched-capacitor circuit 20B may further include a switch S232 for disconnecting the flying capacitors C204 and C206 from each other and a switch S233 for disconnecting the flying capacitors C205 and C207 from each other.

In this case, the switched-capacitor circuit 20B is configured to implement a fourth mode that generates three discrete voltages V4, V5, and V6, in addition to the above-described first, second, and third modes.

In a first phase of the fourth mode, the switches S212, S215, S216, S219, S220, and S223 included in a seventh set are closed, whereas the switches S213, S214, S217, S218, S221, and S222 included in an eighth set are opened. Furthermore, the switches S200, S201, S202, S203, S204, S205, S206, S207, S208, S209, S210, and S211 are closed, whereas the switches S224, S225, S230, S231, S232, and S233 are opened.

In a second phase of the fourth mode, the switches S212, S215, S216, S219, S220, and S223 included in the seventh set are opened, whereas the switches S213, S214, S217, S218, S221, and S222 included in the eighth set are closed. Furthermore, the switches S200, S201, S202, S203, S204, S205, S206, S207, S208, S209, S210, and S211 are closed, whereas the switches S224, S225, S230, S231, S232, and S233 are opened.

In this way, in the fourth mode, the seventh set of switches and the eighth set of switches are alternately opened and closed in the first phase and the second phase. On the other hand, the switches S200, S201, S202, S203, S204, S205, S206, S207, S208, S209, S210, and S211 are kept closed in the first phase and the second phase, whereas the switches S224, S225, S230, S231, S232, and S233 are kept open in the first phase and the second phase.

Accordingly, the switched-capacitor circuit 20B is configured to maintain multiple discrete voltages V4, V5, and V6 satisfying (V6 - V5):(V5 - V4):(V4 - VG) = 1:1:1 at the three nodes N4, N5, and N6 labeled V4, V5, and V6, respectively. For example, when the regulated voltage Vcnv supplied from the pre-regulator circuit 10 is 5 V, the switched-capacitor circuit 20B is configured to generate 2.5 V, 5 V, and 7.5 V as the three discrete voltages V4, V5, and V6 in the fourth mode.

As illustrated in FIG. 9, the switched-capacitor circuit 20B may further include a switch S234 for disconnecting the flying capacitors C206 and C208 from each other and a switch S235 for disconnecting the flying capacitors C207 and C209 from each other.

In this case, the switched-capacitor circuit 20B is configured to implement a fifth mode that generates two discrete voltages V5 and V6, in addition to the above-described first, second, third, and fourth modes.

In a first phase of the fifth mode, the switches S216, S219, S220, and S223 included in a ninth set are closed, whereas the switches S217, S218, S221, and S222 included in a tenth set are opened. Furthermore, the switches S200, S201, S202, S203, S204, S205, S206, S207, S208, S209, S210, S211, S212, S213, S214, and S215 are closed, whereas the switches S224, S225, S230, S231, S232, S233, S234, and S235 are opened.

In a second phase of the fifth mode, the switches S216, S219, S220, and S223 included in the ninth set are opened, whereas the switches S217, S218, S221, and S222 included in the tenth set are closed. Furthermore, the switches S200, S201, S202, S203, S204, S205, S206, S207, S208, S209, S210, S211, S212, S213, S214, and S215 are closed, whereas the switches S224, S225, S230, S231, S232, S233, S234, and S235 are opened.

In this way, in the fifth mode, the ninth set of switches and the tenth set of switches are alternately opened and closed in the first phase and the second phase. On the other hand, the switches S200, S201, S202, S203, S204, S205, S206, S207, S208, S209, S210, S211, S212, S213, S214, and S215 are kept closed in the first phase and the second phase, whereas the switches S224, S225, S230, S231, S232, S233, S234, and S235 are kept open in the first phase and the second phase.

Accordingly, the switched-capacitor circuit 20B is configured to maintain multiple discrete voltages V5 and V6 satisfying (V6 - V5):(V5 - VG) = 1:1 at the two nodes N5 and N6 labeled V5, and V6, respectively. For example, when the regulated voltage Vcnv supplied from the pre-regulator circuit 10 is 5 V, the switched-capacitor circuit 20B is configured to generate 5 V and 10 V as the two discrete voltages V5 and V6 in the fifth mode.

As described above, in the tracker circuit 1 according to the present modification, the switched-capacitor circuit 20B further includes the flying capacitors C204 and C205; the smoothing capacitor C213 and the switches S212, S213, S214, S215, S230, and S231. One end of the switch S208 and one end of the switch S209 are switchably connected to the other of the two electrodes of the flying capacitor C202 via the switch S230, and are connected to one of the two electrodes of the flying capacitor C204. One end of the switch S210 and one end of the switch S211 are switchably connected to the other of the two electrodes of the flying capacitor C203 via the switch S231, and are connected to one of the two electrodes of the flying capacitor C205. One end of the switch S212 and one end of the switch S213 are connected to the other of the two electrodes of the flying capacitor C204. One end of the switch S214 and one end of the switch S215 are connected to the other of the two electrodes of the flying capacitor C205. The other end of the switch S209, the other end of the switch S211, the other end of the switch S212, and the other end of the switch S214 are connected to the other of the two electrodes of the smoothing capacitor C212 and one of the two electrodes of the smoothing capacitor C213. The other end of the switch S213 and the other end of the switch S215 are connected to the other of the two electrodes of the smoothing capacitor C213. One end of the switch S230 is connected to the other of the two electrodes of the flying capacitor C202. The other end of the switch S230 is connected to the one of the two electrodes of the flying capacitor C204. One end of the switch S231 is connected to the other of the two electrodes of the flying capacitor C203. The other end of the switch S231 is connected to the one of the two electrodes of the flying capacitor C205.

Accordingly, the switch S230 is configured to disconnect the flying capacitors C202 and C204 from each other, and the switch S231 is configured to disconnect the flying capacitors C203 and C205 from each other. Thus, it is possible to switch the flying capacitors C202 and C203 between enabled and disabled states in the switched-capacitor circuit 20B. As a result, it is possible to further increase the range of variations of the number of multiple discrete voltages that can be generated by the switched-capacitor circuit 20B. This makes it possible to generate multiple discrete voltages more suitable for the RF signal amplified by the power amplifier 2, thereby further improving power efficiency in the D-ET mode.

### SECOND EXEMPLARY EMBODIMENT

Next, a second exemplary embodiment will be described. The present exemplary embodiment is different from the first exemplary embodiment mainly in the circuit configuration of the switched-capacitor circuit. Hereinafter, the present exemplary embodiment will be described with a focus on differences from the first exemplary embodiment with reference to the drawings.

### 2.1 Circuit configurations of communication device 7A and tracker circuit 1A

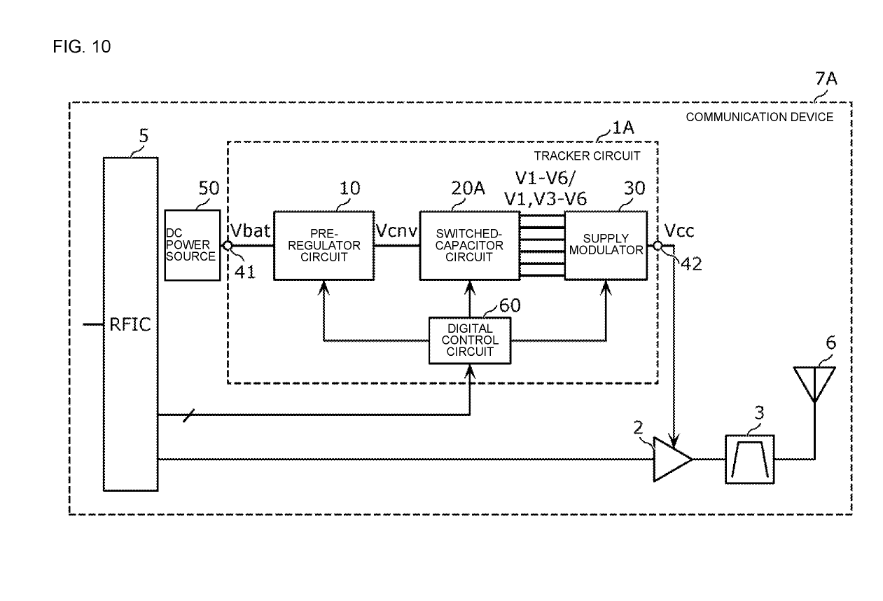

First, the circuit configuration of a communication device 7A according to the present exemplary embodiment will be described with reference to FIG. 10. FIG. 10 is a circuit configuration diagram of the communication device 7A according to the present exemplary embodiment.

FIG. 10 illustrates an exemplary circuit configuration. The communication device 7A can be implemented by using any of a wide variety of circuit implementations and circuit techniques. Thus, the description of the communication device 7A provided below is not to be construed in a limiting manner.

The communication device 7A is similar to the communication device 7 according to the first exemplary embodiment except that a tracker circuit 1A is included instead of the tracker circuit 1. Thus, the description of the communication device 7A is omitted except for the description of the tracker circuit 1A.

The tracker circuit 1A is configured to supply a power supply voltage Vcc to the power amplifier 2 in the D-ET mode. Furthermore, the tracker circuit 1A may supply the power supply voltage Vcc to the power amplifier 2 in the APT mode. As illustrated in FIG. 10 the tracker circuit 1A includes a pre-regulator circuit 10, a switched-capacitor circuit 20A, a supply modulator 30, an input terminal 41, an output terminal 42, and a digital control circuit 60.

That is, the tracker circuit 1A is similar to the tracker circuit 1 according to the first exemplary embodiment except that the switched-capacitor circuit 20A is included instead of the switched-capacitor circuit 20. Thus, the description of the tracker circuit 1A is omitted except for the description of the switched-capacitor circuit 20A.

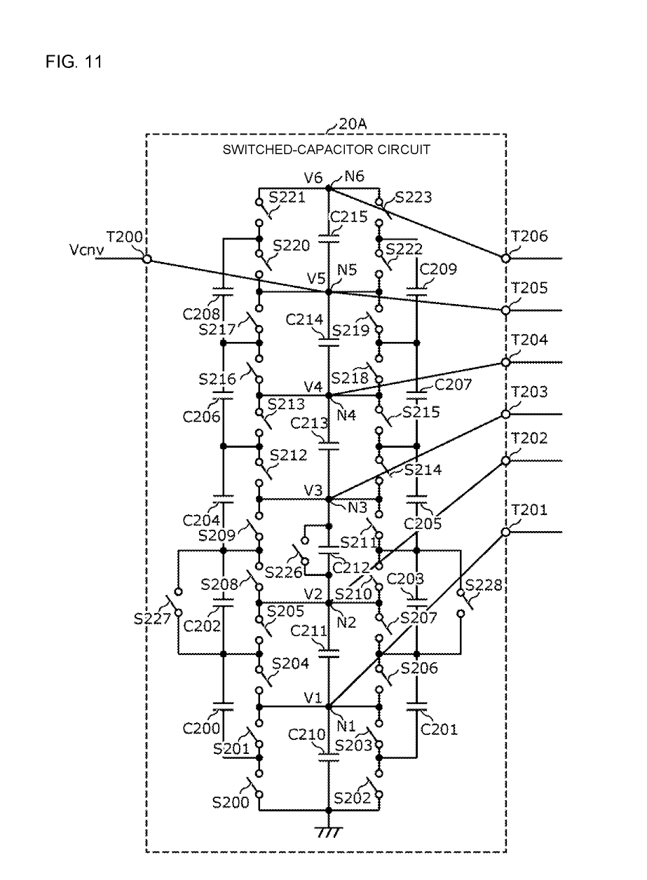

The switched-capacitor circuit 20A is configured to generate, based on the regulated voltage Vcnv supplied by the pre-regulator circuit 10, multiple discrete voltages V1, V2, V3, V4, V5, and V6, or V1, V3, V4, V5, and V6. In some examples, the switched-capacitor circuit 20A has a first mode that generates multiple discrete voltages V1, V2, V3, V4, V5, and V6 (an example of multiple first discrete voltages) from the regulated voltage Vcnv, and a second mode that generates multiple discrete voltages V1, V3, V4, V5, and V6 (an example of multiple second discrete voltages) from the regulated voltage Vcnv. In this case, the number of the multiple discrete voltages V1, V2, V3, V4, V5, and V6 generated in the first mode is greater than the number of the multiple discrete voltages V1, V3, V4, V5, and V6 generated in the second mode. A detailed circuit configuration of the switched-capacitor circuit 20A will be described below with reference to FIG. 11.

### 2.2 Circuit configuration of switched-capacitor circuit 20A

The circuit configuration of the switched-capacitor circuit 20A will be described with reference to FIG. 11. FIG. 11 is a circuit configuration diagram of the switched-capacitor circuit 20A according to the present exemplary embodiment.

FIG. 11 illustrates an exemplary circuit configuration. The switched-capacitor circuit 20A can be implemented by using any of a wide variety of circuit implementations and circuit techniques. Thus, the description of the switched-capacitor circuit 20A provided below is not to be construed in a limiting manner.

The switched-capacitor circuit 20A has a ladder circuit configuration and is configured to generate multiple discrete voltages V1, V2, V3, V4, V5, and V6, or V1, V3, V4, V5, and V6. In some examples, the switched-capacitor circuit 20A includes flying capacitors C200 to C209, smoothing capacitors C210 to C215, switches S200 to S223 and S226 to S228, an input terminal T200, and output terminals T201 to T206. Energy and electric charge are input from the pre-regulator circuit 10 to a node N5 via the input terminal T200, and are withdrawn from nodes N1, N2, N3, N4, N5, and N6 to the supply modulator 30 via the output terminals T201, T202, T203, T204, T205, and T206.

In the present exemplary embodiment, the flying capacitors C202, C203, C204, and C205 are respective examples of a first flying capacitor, a second flying capacitor, a third flying capacitor, and a fourth flying capacitor. The smoothing capacitors C211, C212, and C213 are respective examples of a first smoothing capacitor, a second smoothing capacitor, and a third smoothing capacitor. The switches S204, S205, S206, S207, S208, S209, S210, S211, S212, S213, S214, and S215 are respective examples of a first switch, a second switch, a third switch, a fourth switch, a fifth switch, a sixth switch, a seventh switch, an eighth switch, a ninth switch, a tenth switch, an eleventh switch, and a twelfth switch.

The switch S226 is an example of a thirteenth switch and is connected between the two electrodes of the smoothing capacitor C212. In some examples, one end of the switch S226 is connected to one of the two electrodes of the smoothing capacitor C212. On the other hand, the other end of the switch S226 is connected to the other of the two electrodes of the smoothing capacitor C212. Closing the switch S226 short-circuits the two electrodes of the smoothing capacitor C212.

The switch S227 is an example of a fourteenth switch and is connected between the two electrodes of the flying capacitor C202. In some examples, one end of the switch S227 is connected to one of the two electrodes of the flying capacitor C202. On the other hand, the other end of the switch S227 is connected to the other of the two electrodes of the flying capacitor C202. Closing the switch S227 short-circuits the two electrodes of the flying capacitor C202. The switch S227 is optional and does not necessarily have to be included in the switched-capacitor circuit 20A.

The switch S228 is an example of a fifteenth switch and is connected between the two electrodes of the flying capacitor C203. In some examples, one end of the switch S228 is connected to one of the two electrodes of the flying capacitor C203. On the other hand, the other end of the switch S228 is connected to the other of the two electrodes of the flying capacitor C203. Closing the switch S228 short-circuits the two electrodes of the flying capacitor C203. The switch S228 is optional and does not necessarily have to be included in the switched-capacitor circuit 20A.

### 2.3 Method for controlling switched-capacitor circuit 20A

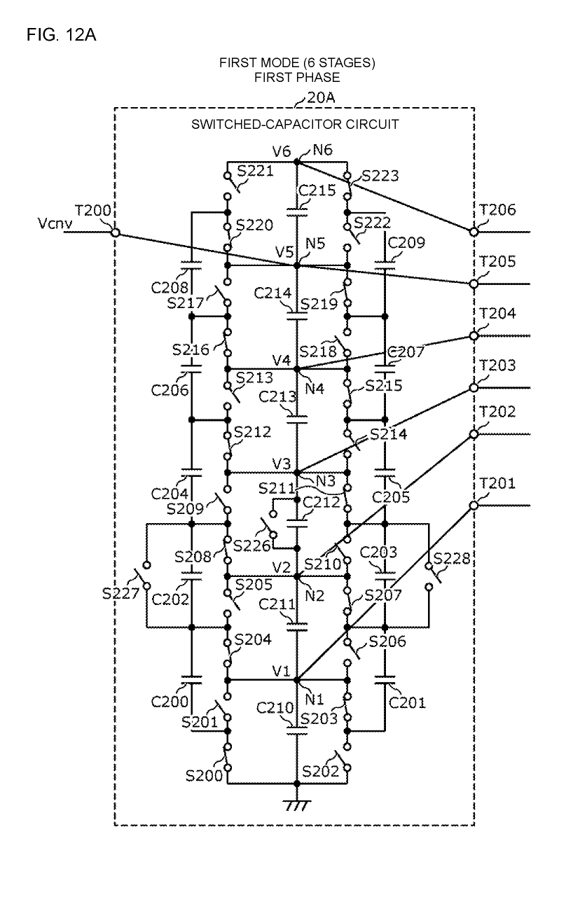

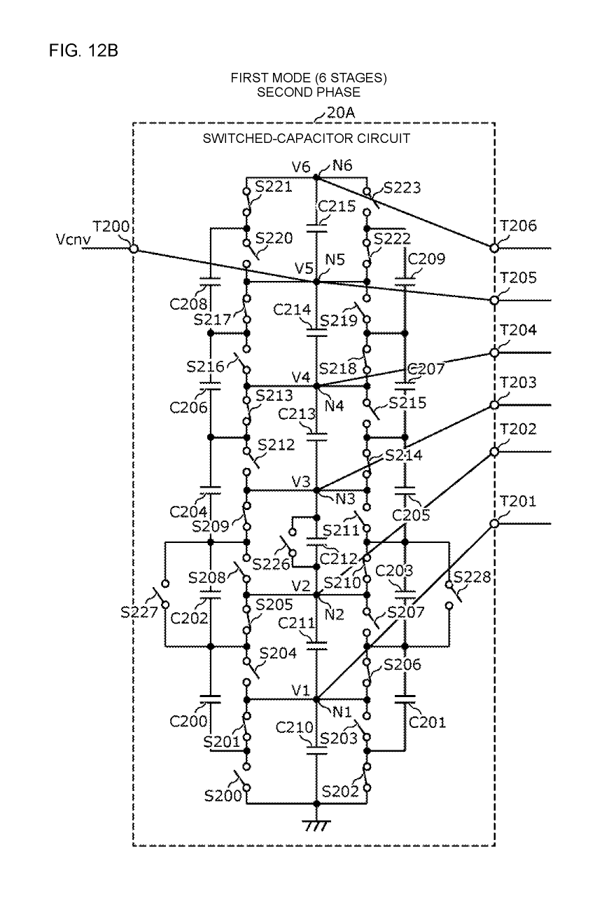

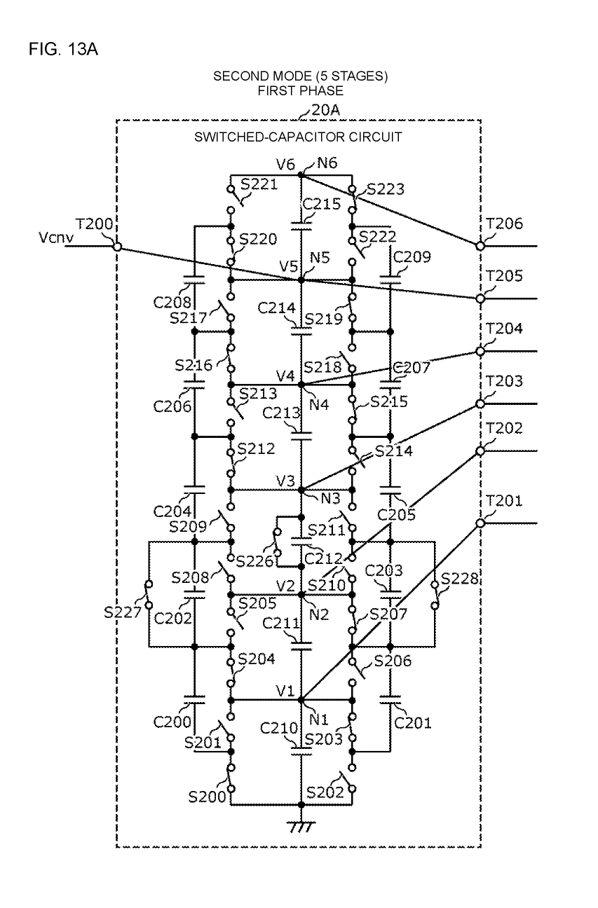

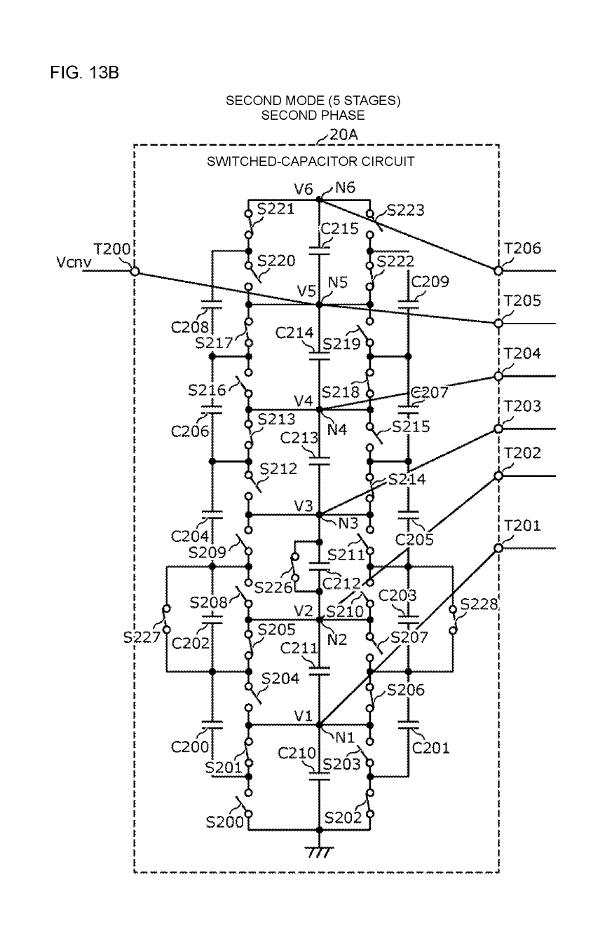

Next, a method for controlling the switched-capacitor circuit 20A according to the present exemplary embodiment will be described with reference to FIG. 12A, FIG. 12B, FIG. 13A, and FIG. 13B.

### 2.3.1 First mode

First, the first mode will be described with reference to FIG. 12A and FIG. 12B. FIG. 12A is a circuit configuration diagram illustrating a connection state in a first phase of the first mode of the switched-capacitor circuit 20A according to the present exemplary embodiment. FIG. 12B is a circuit configuration diagram illustrating a connection state in a second phase of the first mode of the switched-capacitor circuit 20A according to the present exemplary embodiment.

The first mode is a mode in which the switched-capacitor circuit 20A generates six discrete voltages V1, V2, V3, V4, V5, and V6. That is, in the first mode, the switched-capacitor circuit 20A operates as a six-stage switched-capacitor.

In the first mode, the first phase and the second phase are alternately repeated based on the control signal CS20 from the digital control circuit 60.

In the first phase of the first mode, as illustrated in FIG. 12A, the switches S200, S203, S204, S207, S208, S211, S212, S215, S216, S219, S220, and S223 included in a first set are closed, whereas the switches S201, S202, S205, S206, S209, S210, S213, S214, S217, S218, S221, and S222 included in a second set are opened. Furthermore, the switches S226, S227, and S228 are opened.

In the second phase of the first mode, as illustrated in FIG. 12B, the switches S200, S203, S204, S207, S208, S211, S212, S215, S216, S219, S220, and S223 included in the first set are opened, whereas the switches S201, S202, S205, S206, S209, S210, S213, S214, S217, S218, S221, and S222 included in the second set are closed. Furthermore, the switches S226, S227, and S228 are opened.

In this way, in the first mode, the first set of switches and the second set of switches are alternately opened and closed in the first phase and the second phase. On the other hand, the switches S226, S227, and S228 are kept open in the first phase and the second phase.

As a result of the first phase and the second phase being repeated, the flying capacitors C200, C201, C202, C203, C204, C205, C206, C207, C208, and C209 are configured to perform charging and discharging in a complementary manner. For example, in one of the first phase and the second phase, charging from the flying capacitors C200, C202, C204, C206, and C208 to the smoothing capacitors C210, C211, C212, C213, C214, and C215 is performed. In the other of the first phase and the second phase, charging from the flying capacitors C201, C203, C205, C207, and C209 to the smoothing capacitors C210, C211, C212, C213, C214, and C215 is performed. That is, the smoothing capacitors C210, C211, C212, C213, C214, and C215 are constantly charged from any of the flying capacitors C200, C201, C202, C203, C204, C205, C206, C207, C208, and C209. Thus, even when a current rapidly flows from any of the nodes N1, N2, N3, N4, N5, and N6 to the supply modulator 30, electric charge is rapidly replenished at any of the nodes N1, N2, N3, N4, N5, and N6, and potential variations at the nodes N1, N2, N3, N4, N5, and N6 can be reduced.

As a result of operating in the above-described manner, the switched-capacitor circuit 20A is configured to maintain substantially equal voltages across each of the smoothing capacitors C210, C211, C212, C213, C214, and C215. In some examples, at the six nodes N1, N2, N3, N4, N5, and N6 labeled V1, V2, V3, V4, V5, and V6, respectively, the multiple discrete voltages V1, V2, V3, V4, V5, and V6 satisfying (V6 - V5):(V5 - V4):(V4 - V3):(V3 - V2):(V2 - V1):(V1 - VG) = 1:1:1:1:1:1 are maintained. For example, when the regulated voltage Vcnv supplied from the pre-regulator circuit 10 is 5 V, the switched-capacitor circuit 20A is configured to generate 1 V, 2 V, 3 V, 4 V, 5 V, and 6 V as the six discrete voltages V1, V2, V3, V4, V5, and V6.

### 2.3.2 Second mode

Next, the second mode will be described with reference to FIG. 13A and FIG. 13B. FIG. 13A is a circuit configuration diagram illustrating a connection state in a first phase of the second mode of the switched-capacitor circuit 20A according to the present exemplary embodiment. FIG. 13B is a circuit configuration diagram illustrating a connection state in a second phase of the second mode of the switched-capacitor circuit 20A according to the present exemplary embodiment.

The second mode is a mode in which the switched-capacitor circuit 20A generates five discrete voltages V1, V3, V4, V5, and V6. That is, in the second mode, the switched-capacitor circuit 20A operates as a five-stage switched-capacitor.

In the second mode, the first phase and the second phase are alternately repeated based on the control signal CS20 from the digital control circuit 60.

In the first phase of the second mode, as illustrated in FIG. 13A, the switches S200, S203, S204, S207, S212, S215, S216, S219, S220, and S223 included in a third set are closed, whereas the switches S201, S202, S205, S206, S213, S214, S217, S218, S221, and S222 included in a fourth set are opened. Furthermore, the switches S208, S209, S210, and S211 are opened, whereas the switches S226, S227, and S228 are closed.

In the second phase of the second mode, as illustrated in FIG. 13B, the switches S200, S203, S204, S207, S212, S215, S216, S219, S220, and S223 included in the third set are opened, whereas the switches S201, S202, S205, S206, S213, S214, S217, S218, S221, and S222 included in the fourth set are closed. Furthermore, the switches S208, S209, S210, and S211 are opened, whereas the switches S226, S227, and S228 are closed.

In this way, in the second mode, the third set of switches and the fourth set of switches are alternately opened and closed in the first phase and the second phase. On the other hand, the switches S208, S209, S210, and S211 are kept open in the first phase and the second phase, whereas the switches S226, S227, and S228 are kept closed in the first phase and the second phase.

As a result of the first phase and the second phase being repeated, the flying capacitors C200, C201, C204, C205, C206, C207, C208, and C209 are configured to perform charging and discharging in a complementary manner. For example, in one of the first phase and the second phase, charging from the flying capacitors C200, C204, C206, and C208 to the smoothing capacitors C210, C211, C213, C214, and C215 is performed. In the other of the first phase and the second phase, charging from the flying capacitors C201, C205, C207, and C209 to the smoothing capacitors C210, C211, C213, C214, and C215 is performed. That is, the smoothing capacitors C210, C211, C213, C214, and C215 are constantly charged from any of the flying capacitors C200, C201, C204, C205, C206, C207, C208, and C209. Thus, even when a current rapidly flows from any of the nodes N1, N3, N4, N5, and N6 to the supply modulator 30, electric charge is rapidly replenished at any of the nodes N1, N3, N4, N5, and N6, and potential variations at the nodes N1, N3, N4, N5, and N6 can be reduced.

As a result of operating in the above-described manner, the switched-capacitor circuit 20A is configured to maintain substantially equal voltages across each of the smoothing capacitors C210, C211, C213, C214, and C215. In some examples, at the five nodes N1, N3, N4, N5, and N6 labeled V1, V3, V4, V5, and V6, respectively, the multiple discrete voltages V1, V3 (= V2), V4, V5, and V6 satisfying (V6 - V5):(V5 - V4):(V4 - V3):(V3 - V1):(V1 - VG) = 1:1:1:1:1 are maintained. For example, when the regulated voltage Vcnv supplied from the pre-regulator circuit 10 is 5 V, the switched-capacitor circuit 20A is configured to generate 1.25 V, 2.5 V, 3.75 V, 5 V, and 6.25 V as the five discrete voltages V1, V3, V4, V5, and V6.

### 2.4 Multiple discrete voltages generated in first mode and second mode

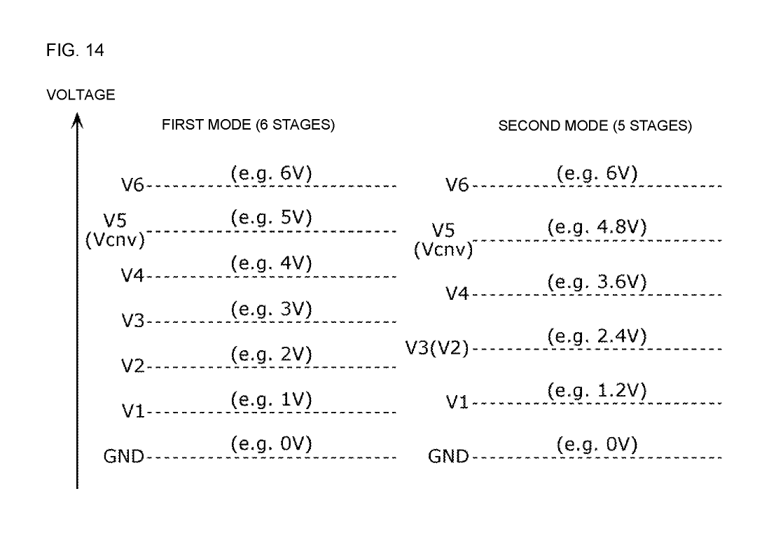

Next, multiple discrete voltages generated by the switched-capacitor circuit 20A according to the present exemplary embodiment will be described with reference to FIG. 14. FIG. 14 is a diagram illustrating an example of multiple discrete voltages generated by the switched-capacitor circuit 20A according to the present exemplary embodiment. In FIG. 14, the power supply voltage Vcc corresponding to the peak power of the RF signal amplified by the power amplifier 2 is 6 V.

For example, in the first mode, a regulated voltage Vcnv of 5 V is supplied from the pre-regulator circuit 10 to the switched-capacitor circuit 20A. In this case, the switched-capacitor circuit 20A is configured to generate six discrete voltages of 1 V, 2 V, 3 V, 4 V, 5 V, and 6 V.

For example, in the second mode, a regulated voltage Vcnv of 4.8 V is supplied from the pre-regulator circuit 10 to the switched-capacitor circuit 20A. In this case, the switched-capacitor circuit 20A is configured to generate five discrete voltages of 1.2 V, 2.4 V, 3.6 V, 4.8 V, and 6 V.

In the present exemplary embodiment, as in the first exemplary embodiment, power efficiency can be improved by applying the second mode to the switched-capacitor circuit 20A when the PAPR of the RF signal is higher than or equal to the threshold, and applying the first mode to the switched-capacitor circuit 20A when the PAPR of the RF signal is lower than the threshold.

### 2.5 Conclusion

As described above, the tracker circuit 1A according to the present exemplary embodiment includes the switched-capacitor circuit 20A configured to generate multiple discrete voltages from an input voltage; and the supply modulator 30 configured to selectively output, to the power amplifier 2, at least one of the multiple discrete voltages that have been generated. The switched-capacitor circuit 20A includes the flying capacitors C202, C203, C204, and C205; the smoothing capacitors C211, C212, and C213; and the switches S204, S205, S206, S207, S208, S209, S210, S211, S212, S213, S214, S215, and S226. One end of the switch S204 and one end of the switch S205 are connected to one of the two electrodes of the flying capacitor C202. One end of the switch S206 and one end of the switch S207 are connected to one of the two electrodes of the flying capacitor C203. One end of the switch S208 and one end of the switch S209 are connected to the other of the two electrodes of the flying capacitor C202 and one of the two electrodes of the flying capacitor C204. One end of the switch S210 and one end of the switch S211 are connected to the other of the two electrodes of the flying capacitor C203 and one of the two electrodes of the flying capacitor C205. One end of the switch S212 and one end of the switch S213 are connected to the other of the two electrodes of the flying capacitor C204. One end of the switch S214 and one end of the switch S215 are connected to the other of the two electrodes of the flying capacitor C205. The other end of the switch S204, the other end of the switch S206, and one of the two electrodes of the smoothing capacitor C211 are connected to each other. The other end of the switch S205, the other end of the switch S207, the other end of the switch S208, and the other end of the switch S210 are connected to the other of the two electrodes of the smoothing capacitor C211 and one of the two electrodes of the smoothing capacitor C212. The other end of the switch S209, the other end of the switch S211, the other end of the switch S212, and the other end of the switch S214 are connected to the other of the two electrodes of the smoothing capacitor C212 and one of the two electrodes of the smoothing capacitor C213. The other end of the switch S213 and the other end of the switch S215 are connected to the other of the two electrodes of the smoothing capacitor C213. One end and the other end of the switch S226 are respectively connected to the one and the other of the two electrodes of the smoothing capacitor C211, C212, or C213.

Accordingly, the switch S226 can short-circuit the smoothing capacitor C211, C212, or C213. Thus, it is possible to switch the smoothing capacitor C211, C212, or C213 between enabled and disabled states in the switched-capacitor circuit 20A. As a result, it is possible to increase the range of variations of the number of multiple discrete voltages that can be generated by the switched-capacitor circuit 20A. This makes it possible to generate multiple discrete voltages more suitable for the RF signal amplified by the power amplifier 2, thereby improving power efficiency in the D-ET mode.

For example, in the tracker circuit 1A according to the present exemplary embodiment, the one end and the other end of the switch S226 may be respectively connected to the one and the other of the two electrodes of the smoothing capacitor C212. When the PAPR of the RF signal amplified by the power amplifier 2 is lower than a threshold, the switch S226 may be kept open; and when the PAPR is higher than or equal to the threshold, the switch S208, the switch S209, the switch S210, and the switch S211 may be kept open, and the switch S226 may be kept closed.

Accordingly, it is possible to reduce the number of multiple discrete voltages when the PAPR of the RF signal amplified by the power amplifier 2 is high. The average power of an RF signal having a higher PAPR is lower than the average power of an RF signal having a lower PAPR when the RF signals have the same peak power. As illustrated in FIG. 7, when the number of voltages that can be supplied in the D-ET mode is limited, a smaller number of multiple discrete voltages makes it possible to track the envelope signal of the RF signal down to a lower voltage. Thus, as a result of reducing the number of multiple discrete voltages when the PAPR of the RF signal amplified by the power amplifier 2 is high, power efficiency can be improved in the D-ET mode.

For example, in the tracker circuit 1A according to the present exemplary embodiment, the switched-capacitor circuit 20A may further include the switch S227 and the switch S228. The one end and the other end of the switch S226 may be respectively connected to the one and the other of the two electrodes of the smoothing capacitor C212. One end and the other end of the switch S227 may be respectively connected to the one and the other of the two electrodes of the flying capacitor C202. One end and the other end of the switch S228 may be respectively connected to the one and the other of the two electrodes of the flying capacitor C203.

Accordingly, the switch S227 can short-circuit the flying capacitor C202, and the switch S228 can short-circuit the flying capacitor C203. Thus, closing the switches S227 and S228 when the switch S226 is closed makes it possible to disconnect the series connection between the flying capacitor C204 and the flying capacitor C202, and disconnect the series connection between the flying capacitor C205 and the flying capacitor C203. As a result, it is possible to suppress a decrease in the capacitance of the flying capacitors and reduce changes in the voltage supplied by the switched-capacitor circuit 20A.

For example, in the tracker circuit 1A according to the present exemplary embodiment, when the PAPR of the RF signal amplified by the power amplifier 2 is lower than a threshold, the switch S226, the switch S227, and the switch S228 may be kept open; and when the PAPR is higher than or equal to the threshold, the switch S208, the switch S209, the switch S210, and the switch S211 may be kept open, and the switch S226, the switch S227, and the switch S228 may be kept closed.

Accordingly, it is possible to reduce the number of multiple discrete voltages when the PAPR of the RF signal amplified by the power amplifier 2 is high. The average power of an RF signal having a higher PAPR is lower than the average power of an RF signal having a lower PAPR when the RF signals have the same peak power. As illustrated in FIG. 7, when the number of voltages that can be supplied in the D-ET mode is limited, a smaller number of multiple discrete voltages makes it possible to track the envelope signal of the RF signal down to a lower voltage. Thus, as a result of reducing the number of multiple discrete voltages when the PAPR of the RF signal amplified by the power amplifier 2 is high, power efficiency can be improved in the D-ET mode.

The tracker circuit 1A according to the present exemplary embodiment includes the switched-capacitor circuit 20A having a first mode that generates multiple first discrete voltages from an input voltage and a second mode that generates multiple second discrete voltages from the input voltage; and the supply modulator 30 configured to selectively output, to the power amplifier 2, at least one of the multiple first discrete voltages that have been generated or at least one of the multiple second discrete voltages that have been generated. The number of the multiple first discrete voltages is greater than the number of the multiple second discrete voltages.

Accordingly, it is possible to switch the number of multiple discrete voltages generated by the switched-capacitor circuit 20A. Thus, it is possible to generate multiple discrete voltages more suitable for the RF signal amplified by the power amplifier 2, thereby improving power efficiency in the D-ET mode.

### Modification of Second Exemplary Embodiment

The switched-capacitor circuit 20A according to the second exemplary embodiment includes the switch S226 for short-circuiting the smoothing capacitor C212. Alternatively, the switched-capacitor circuit 20A may include, instead of or in addition to the switch S226, a switch for short-circuiting the smoothing capacitor C210, C211, C213, C214, or C215, or any combination thereof.

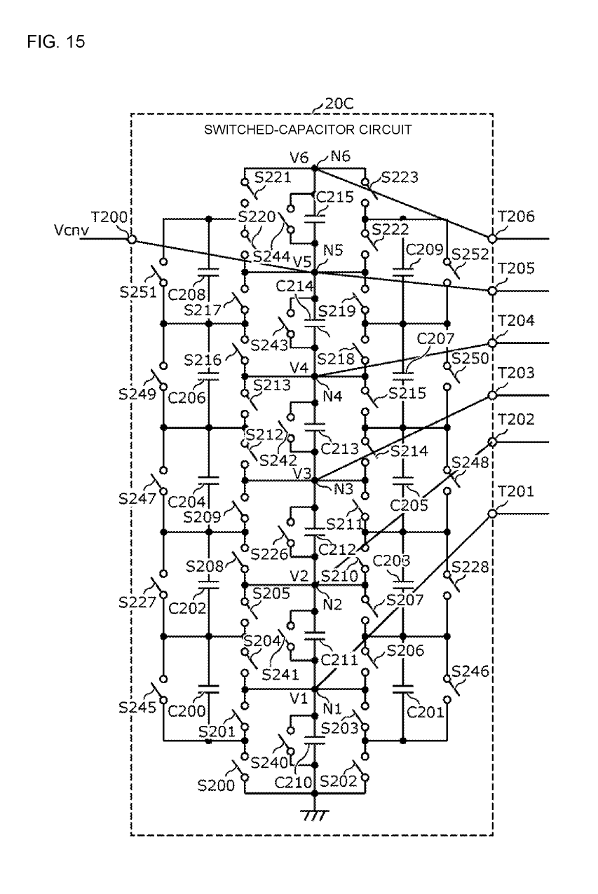

For example, as illustrated in FIG. 15, a switched-capacitor circuit 20C according to the present modification may include a switch S242 for short-circuiting the smoothing capacitor C213, and may further include switches S247 and S248 for short-circuiting the flying capacitors C204 and C205, respectively.

The switch S242 is an example of a sixteenth switch and is connected between the two electrodes of the smoothing capacitor C213. In some examples, one end of the switch S242 is connected to one of the two electrodes of the smoothing capacitor C213. On the other hand, the other end of the switch S242 is connected to the other of the two electrodes of the smoothing capacitor C213. Closing the switch S242 short-circuits the two electrodes of the smoothing capacitor C213.

The switch S247 is an example of a seventeenth switch and is connected between the two electrodes of the flying capacitor C204. In some examples, one end of the switch S247 is connected to one of the two electrodes of the flying capacitor C204. On the other hand, the other end of the switch S247 is connected to the other of the two electrodes of the flying capacitor C204. Closing the switch S247 short-circuits the two electrodes of the flying capacitor C204. The switch S247 is optional and does not necessarily have to be included in the switched-capacitor circuit 20C.

The switch S248 is an example of an eighteenth switch and is connected between the two electrodes of the flying capacitor C205. In some examples, one end of the switch S248 is connected to one of the two electrodes of the flying capacitor C205. On the other hand, the other end of the switch S248 is connected to the other of the two electrodes of the flying capacitor C205. Closing the switch S248 short-circuits the two electrodes of the flying capacitor C205. The switch S248 is optional and does not necessarily have to be included in the switched-capacitor circuit 20C.

In the above-described second mode, for example, the switches S212, S213, S214, and S215 may be kept open in the first phase and the second phase instead of the switches S208, S209, S210, and S211, and the switches S242, S247, and S248 may be kept closed in the first phase and the second phase instead of the switches S226, S227, and S228. Accordingly, the switched-capacitor circuit 20C is configured to generate five discrete voltages V1, V2, V4 (= V3), V5, and V6.

Furthermore, the switched-capacitor circuit 20C is configured to implement, for example, a third mode that generates four discrete voltages V1, V4, V5, and V6, in addition to the above-described first and second modes.

In a first phase of the third mode, for example, the switches S200, S203, S204, S207, S216, S219, S220, and S223 included in a fifth set are closed, whereas the switches S201, S202, S205, S206, S217, S218, S221, and S222 included in a sixth set are opened. Furthermore, the switches S208, S209, S210, S211, S212, S213, S214, and S215 are opened, whereas the switches S226, S227, S228, S242, S247, and S248 are closed.

In a second phase of the third mode, for example, the switches S200, S203, S204, S207, S216, S219, S220, and S223 included in the fifth set are opened, whereas the switches S201, S202, S205, S206, S217, S218, S221, and S222 included in the sixth set are closed. Furthermore, the switches S208, S209, S210, S211, S212, S213, S214, and S215 are opened, whereas the switches S226, S227, S228, S242, S247, and S248 are closed.

In this way, in the third mode, the fifth set of switches and the sixth set of switches are alternately opened and closed in the first phase and the second phase. On the other hand, the switches S208, S209, S210, S211, S212, S213, S214, and S215 are kept open in the first phase and the second phase, whereas the switches S226, S227, S228, S242, S247, and S248 are kept closed in the first phase and the second phase.

Accordingly, the switched-capacitor circuit 20C is configured to maintain multiple discrete voltages V1, V4 (= V3 = V2), V5, and V6 satisfying (V6 - V5):(V5 - V4):(V4 - V1):(V1 - VG) = 1:1:1:1 at the four nodes N1, N4, N5, and N6 labeled V1, V4, V5, and V6, respectively. For example, when the regulated voltage Vcnv supplied from the pre-regulator circuit 10 is 5 V, the switched-capacitor circuit 20C is configured to generate 1.67 V, 3.33 V, 5 V, and 6.67 V as the four discrete voltages V1, V4, V5, and V6 in the third mode.

The switched-capacitor circuit 20C may include, instead of or in addition to the switch S242, a switch S240, a switch S241, a switch S243, a switch S244, or any combination thereof, as illustrated in FIG. 15. Also, the switched-capacitor circuit 20C may include, instead of or in addition to a set of the switches S247 and S248, a set of switches S245 and S246, a set of switches S249 and S250, a set of switches S251 and S252, or any combination thereof.

As described above, in the tracker circuit 1A according to the present modification, the switched-capacitor circuit 20C may further include the switch S242, and one end and the other end of the switch S242 may be respectively connected to one and the other of the two electrodes of the smoothing capacitor C213.

Accordingly, the switch S242 can short-circuit the smoothing capacitor C213. Thus, it is possible to switch the smoothing capacitor C213 between enabled and disabled states in the switched-capacitor circuit 20C. As a result, it is possible to increase the range of variations of the number of multiple discrete voltages that can be generated by the switched-capacitor circuit 20C. This makes it possible to generate multiple discrete voltages more suitable for the RF signal amplified by the power amplifier 2, thereby improving power efficiency in the D-ET mode.

For example, in the tracker circuit 1A according to the present modification, the switched-capacitor circuit 20C may further include the switches S247 and S248. One end and the other end of the switch S247 may be respectively connected to one and the other of the two electrodes of the flying capacitor C204. One end and the other end of the switch S248 may be respectively connected to one and the other of the two electrodes of the flying capacitor C205.

Accordingly, the switch S247 can short-circuit the flying capacitor C204, and the switch S248 can short-circuit the flying capacitor C205. Thus, closing the switches S247 and S248 when the switch S242 is closed makes it possible to disconnect the series connection between the flying capacitor C206 and the flying capacitor C204, and disconnect the series connection between the flying capacitor C207 and the flying capacitor C205. As a result, it is possible to suppress a decrease in the capacitance of the flying capacitors and reduce changes in the voltage supplied by the switched-capacitor circuit 20C.

### OTHER EXEMPLARY EMBODIMENTS

The tracker circuit according to the present disclosure has been described above based on the exemplary embodiments. The tracker circuit according to the present disclosure is not limited to the above exemplary embodiments. Another exemplary embodiment implemented by combining any constituent elements in the above exemplary embodiments, modifications obtained by applying various changes conceived by those skilled in the art to the above exemplary embodiments without departing from the gist of the present disclosure, and various devices including the above-described tracker circuit are also included in the present disclosure.

For example, in the circuit configurations of the various circuits according to the above exemplary embodiments, another circuit element, wiring line, and the like may be inserted between individual circuit elements and paths connecting signal paths disclosed in the drawings. For example, an inductor and/or a capacitor may be inserted between the tracker circuit and the power amplifier.

In the switched-capacitor circuits according to the above-described individual exemplary embodiments, the connection relationship between an input terminal and a node may be changed. For example, in the first exemplary embodiment and/or the second exemplary embodiment, the input terminal T200 may be connected to the node N1, N2, N3, N4, or N6 instead of the node N5. Also in this case, an effect similar to that of the first exemplary embodiment and/or the second exemplary embodiment can be obtained.

The tracker circuits according to the above-described individual exemplary embodiments may each include multiple supply modulators. In this case, the tracker circuits are configured to supply different voltages to multiple power amplifiers.

The switched-capacitor circuits according to the above-described individual exemplary embodiments each have a circuit configuration configured to generate up to six discrete voltages. Alternatively, the switched-capacitor circuits may each have a circuit configuration configured to generate up to three, four, five, or seven or more discrete voltages. For example, in the first exemplary embodiment, when the switched-capacitor circuit 20 is configured to generate up to three discrete voltages, the switched-capacitor circuit 20 may exclude the flying capacitors C204 to C209, the smoothing capacitors C213 to C215, and the switches S212 to S223.

The present disclosure can be widely used, as a tracker circuit that supplies a voltage to a power amplifier, in communication devices such as mobile phones.

### REFERENCE SIGNS LIST

1, 1A tracker circuit
2 power amplifier
3 filter 5 RFIC
6 antenna
7, 7A communication device
10 pre-regulator circuit
20, 20A, 20B, 20C switched-capacitor circuit
30 supply modulator
41, T101, T200, T301, T302, T303, T304, T305, T306 input terminal
42, T102, T201, T202, T203, T204, T205, T206, T307 output terminal
50 direct current power source
60 digital control circuit
61 first controller
62 second controller
C101 capacitor C200, C201, C202, C203, C204, C205, C206, C207, C208, C209 flying capacitor C210, C211, C212, C213, C214, C215 smoothing capacitor CS10, CS20, CS30 control signal
L101 power inductor
S101, S102, S103, S104, S200, S201, S202, S203, S204, S205, S206, S207, S208, S209, S210, S211, S212, S213, S214, S215, S216, S217, S218, S219, S220, S221, S222, S223, S224, S225, S226, S227, S228, S230, S231, S232, S233, S234, S235, S240, S241, S242, S243, S244, S245, S246, S247, S248, S249, S250, S251, S252, S301, S302, S303, S304, S305, S306 switch

1. A tracker circuit, comprising:
a switched-capacitor circuit configured to generate multiple discrete voltages from an input voltage; and
a supply modulator configured to selectively output, to a power amplifier, at least one of the multiple discrete voltages that have been generated,
wherein:
the switched-capacitor circuit includes: a first flying capacitor, a second flying capacitor, a third flying capacitor, a fourth flying capacitor, a first smoothing capacitor, a second smoothing capacitor, a third smoothing capacitor, a first switch, a second switch, a third switch, a fourth switch, a fifth switch, a sixth switch, a seventh switch, an eighth switch, a ninth switch, a tenth switch, an eleventh switch, a twelfth switch, a thirteenth switch, and a fourteenth switch,
wherein:
a first end of the first switch and a first end of the second switch are connected to a first electrode of two electrodes of the first flying capacitor,
a first end of the third switch and a first end of the fourth switch are connected to a first electrode of two electrodes of the second flying capacitor,
a first end of the fifth switch and a first end of the sixth switch are switchably connected to a second electrode of the two electrodes of the first flying capacitor via the thirteenth switch, and are connected to a first electrode of two electrodes of the third flying capacitor,
a first end of the seventh switch and a first end of the eighth switch are switchably connected to a second electrode of the two electrodes of the second flying capacitor via the fourteenth switch, and are connected to a first electrode of two electrodes of the fourth flying capacitor,
a first end of the ninth switch and a first end of the tenth switch are connected to a second electrode of the two electrodes of the third flying capacitor,
a first end of the eleventh switch and a first end of the twelfth switch are connected to a second electrode of the two electrodes of the fourth flying capacitor,
a second end of the first switch, a second end of the third switch, and a first electrode of two electrodes of the first smoothing capacitor are connected to ground,
a second end of the second switch, a second end of the fourth switch, a second end of the fifth switch, and a second end of the seventh switch are connected to a second electrode of the two electrodes of the first smoothing capacitor and a first electrode of two electrodes of the second smoothing capacitor,
a second end of the sixth switch, a second end of the eighth switch, a second end of the ninth switch, and a second end of the eleventh switch are connected to a second electrode of the two electrodes of the second smoothing capacitor and a first electrode of two electrodes of the third smoothing capacitor,
a second end of the tenth switch and a second end of the twelfth switch are connected to a second electrode of the two electrodes of the third smoothing capacitor,
a first end of the thirteenth switch is connected to the second electrode of the two electrodes of the first flying capacitor,
a second end of the thirteenth switch is connected to the first electrode of the two electrodes of the third flying capacitor,
a first end of the fourteenth switch is connected to the second electrode of the two electrodes of the second flying capacitor, and
a second end of the fourteenth switch is connected to the first electrode of the two electrodes of the fourth flying capacitor.

2. The tracker circuit according to claim 1, wherein:
when a peak-to-average power ratio (PAPR) of a radio frequency signal to be amplified by the power amplifier is lower than a threshold, the thirteenth switch and the fourteenth switch are controlled to be closed, and
when the PAPR is higher than or equal to the threshold, the first switch, the second switch, the third switch, and the fourth switch are controlled to be closed, and the thirteenth switch and the fourteenth switch are controlled to be open.

3. The tracker circuit according to claim 2,
wherein the switched-capacitor circuit further includes a fifth flying capacitor and a sixth flying capacitor, a fourth smoothing capacitor, and a fifteenth switch, a sixteenth switch, a seventeenth switch, an eighteenth switch, a nineteenth switch, and a twentieth switch,
wherein:
the first end of the ninth switch and the first end of the tenth switch are switchably connected to the second electrode of the two electrodes of the third flying capacitor via the nineteenth switch, and are connected to a first electrode of two electrodes of the fifth flying capacitor,
the first end of the eleventh switch and the first end of the twelfth switch are switchably connected to the second electrode of the two electrodes of the fourth flying capacitor via the twentieth switch, and are connected to a first electrode of two electrodes of the sixth flying capacitor,
a first end of the fifteenth switch and a first end of the sixteenth switch are connected to a second electrode of the two electrodes of the fifth flying capacitor,
a first end of the seventeenth switch and a first end of the eighteenth switch are connected to a second electrode of the two electrodes of the sixth flying capacitor,
the second end of the tenth switch, the second end of the twelfth switch, a second end of the fifteenth switch, and a second end of the seventeenth switch are connected to the second electrode of the two electrodes of the third smoothing capacitor and a first electrode of two electrodes of the fourth smoothing capacitor,
a second end of the sixteenth switch and a second end of the eighteenth switch are connected to a second electrode of the two electrodes of the fourth smoothing capacitor,
a first end of the nineteenth switch is connected to the second electrode of the two electrodes of the third flying capacitor,
a second end of the nineteenth switch is connected to the first electrode of the two electrodes of the fifth flying capacitor,
a first end of the twentieth switch is connected to the second electrode of the two electrodes of the fourth flying capacitor, and
a second end of the twentieth switch is connected to the first electrode of the two electrodes of the sixth flying capacitor.

4. A tracker circuit, comprising:
a switched-capacitor circuit configured to generate multiple discrete voltages from an input voltage; and
a supply modulator configured to selectively output, to a power amplifier, at least one of the multiple discrete voltages that have been generated,
wherein the switched-capacitor circuit includes a first flying capacitor, a second flying capacitor, a third flying capacitor, a fourth flying capacitor, a first smoothing capacitor, a second smoothing capacitor, a third smoothing capacitor, a first switch, a second switch, a third switch, a fourth switch, a fifth switch, a sixth switch, a seventh switch, an eighth switch, a ninth switch, a tenth switch, an eleventh switch, a twelfth switch, and a thirteenth switch,
wherein:
a first end of the first switch and a first end of the second switch are connected to a first electrode of two electrodes of the first flying capacitor,
a first end of the third switch and a first end of the fourth switch are connected to a first electrode of two electrodes of the second flying capacitor,
a first end of the fifth switch and a first end of the sixth switch are connected to a second electrode of the two electrodes of the first flying capacitor and a first electrode of two electrodes of the third flying capacitor,
a first end of the seventh switch and a first end of the eighth switch are connected to a second electrode of the two electrodes of the second flying capacitor and a first electrode of two electrodes of the fourth flying capacitor,
a first end of the ninth switch and a first end of the tenth switch are connected to a second electrode of the two electrodes of the third flying capacitor,
a first end of the eleventh switch and a first end of the twelfth switch are connected to a second electrode of the two electrodes of the fourth flying capacitor,
a second end of the first switch, a second end of the third switch, and a first electrode of two electrodes of the first smoothing capacitor are connected to each other,
a second end of the second switch, a second end of the fourth switch, a second end of the fifth switch, and a second end of the seventh switch are connected to a second electrode of the two electrodes of the first smoothing capacitor and a first electrode of two electrodes of the second smoothing capacitor,
a second end of the sixth switch, a second end of the eighth switch, a second end of the ninth switch, and a second end of the eleventh switch are connected to a second electrode of the two electrodes of the second smoothing capacitor and a first electrode of two electrodes of the third smoothing capacitor,
a second end of the tenth switch and a second end of the twelfth switch are connected to a second electrode of the two electrodes of the third smoothing capacitor, and
a first end and a second end of the thirteenth switch are respectively connected to the first electrode of the two electrodes of the first smoothing capacitor and the second electrode of the two electrodes of the first smoothing capacitor, the first electrode of the two electrodes of the second smoothing capacitor and the second electrode of the two electrodes of the second smoothing capacitor or the first electrode of the two electrodes of the third smoothing capacitor and the second electrode of the two electrodes of the third smoothing capacitor.

5. The tracker circuit according to claim 4, wherein:
the first end of the thirteenth switch and the second end of the thirteenth switch are respectively connected to the first electrode of the two electrodes of the second smoothing capacitor and the second electrode of the two electrodes of the second smoothing capacitor,
when a peak-to-average power ratio (PAPR) of a radio frequency signal amplified by the power amplifier is lower than a threshold, the thirteenth switch is controlled to be open, and
when the PAPR is higher than or equal to the threshold, the fifth switch, the sixth switch, the seventh switch, and the eighth switch are controlled to be open, and the thirteenth switch is controlled to be closed.

6. The tracker circuit according to claim 4, wherein:
the switched-capacitor circuit further includes a fourteenth switch and a fifteenth switch,
the first end of the thirteenth switch and the second end of the thirteenth switch are respectively connected to the first electrode of the two electrodes of the second smoothing capacitor and the second electrode of the two electrodes of the second smoothing capacitor,
a first end of the fourteenth switch and a second end of the fourteenth switch are respectively connected to the first electrode of the two electrodes of the first flying capacitor and the second electrode of the two electrodes of the first flying capacitor, and
a first end of the fifteenth switch and a second end of the fifteenth switch are respectively connected to the first electrode of the two electrodes of the second flying capacitor and the second electrode of the two electrodes of the second flying capacitor.

7. The tracker circuit according to claim 6, wherein:
when a peak-to-average power ratio (PAPR) of a radio frequency signal amplified by the power amplifier is lower than a threshold, the thirteenth switch, the fourteenth switch, and the fifteenth switch are controlled to be open, and
when the PAPR is higher than or equal to the threshold, the fifth switch, the sixth switch, the seventh switch, and the eighth switch are controlled to be open, and the thirteenth switch, the fourteenth switch, and the fifteenth switch are controlled to be closed.

8. The tracker circuit according to claim 4, wherein:
the switched-capacitor circuit further includes a sixteenth switch,
the first end of the thirteenth switch and the second end of the thirteenth switch are respectively connected to the first electrode of the two electrodes of the second smoothing capacitor and the second electrode of the two electrodes of the second smoothing capacitor, and
a first end of the sixteenth switch and a second end of the sixteenth switch are respectively connected to the first electrode of the two electrodes of the third smoothing capacitor and the second electrode of the two electrodes of the third smoothing capacitor.

9. The tracker circuit according to claim 8, wherein:
the switched-capacitor circuit further includes a fourteenth switch and a fifteenth switch,
a first end of the fourteenth switch and a second end of the fourteenth switch are respectively connected to the first electrode of the two electrodes of the first flying capacitor and the second electrode of the two electrodes of the first flying capacitor, and
a first end of the fifteenth switch and a second end of the fifteenth switch are respectively connected to the first electrode of the two electrodes of the second flying capacitor and the second electrode of the two electrodes of the second flying capacitor.

10. The tracker circuit according to claim 8, wherein:
the switched-capacitor circuit further includes a seventeenth switch and an eighteenth switch,
a first end of the seventeenth switch and a second end of the seventeenth switch are respectively connected to the first electrode of the two electrodes of the third flying capacitor and the second electrode of the two electrodes of the third flying capacitor, and
a first end of the eighteenth switch and a second end of the eighteenth switch are respectively connected to the first electrode of the two electrodes of the fourth flying capacitor and the second electrode of the two electrodes of the fourth flying capacitor.

11. A tracker circuit, comprising:
a switched-capacitor circuit configured to:
generate, in a first mode, multiple first discrete voltages from an input voltage; and
generate, in a second mode, multiple second discrete voltages from the input voltage, a first number of the multiple first discrete voltages being greater than a second number of the multiple second discrete voltages; and
a supply modulator configured to:
selectively output, to a power amplifier, at least one of the multiple first discrete voltages that have been generated when the switched-capacitor circuit is in the first mode; and
selective output, to the power amplifier, at least one of the multiple second discrete voltages that have been generated when the switched-capacitor circuit is in the second mode.

12. The tracker circuit according to claim 11,
wherein the switched-capacitor circuit includes a first flying capacitor, a second flying capacitor, a third flying capacitor, a fourth flying capacitor, a first smoothing capacitor, a second smoothing capacitor, a third smoothing capacitor, a first switch, a second switch, a third switch, a fourth switch, a fifth switch, a sixth switch, a seventh switch, an eighth switch, a ninth switch, a tenth switch, an eleventh switch, a twelfth switch, a thirteenth switch, and a fourteenth switch,
wherein:
a first end of the first switch and a first end of the second switch are connected to a first electrode of two electrodes of the first flying capacitor,
a first end of the third switch and a first end of the fourth switch are connected to a first electrode of two electrodes of the second flying capacitor,
a first end of the fifth switch and a first end of the sixth switch are switchably connected to a second electrode of the two electrodes of the first flying capacitor via the thirteenth switch, and are connected to a first electrode of two electrodes of the third flying capacitor,
a first end of the seventh switch and a first end of the eighth switch are switchably connected to a second electrode of the two electrodes of the second flying capacitor via the fourteenth switch, and are connected to a first electrode of two electrodes of the fourth flying capacitor,
a first end of the ninth switch and a first end of the tenth switch are connected to a second electrode of the two electrodes of the third flying capacitor,
a first end of the eleventh switch and a first end of the twelfth switch are connected to a second electrode of the two electrodes of the fourth flying capacitor,
a second end of the first switch, a second end of the third switch, and a first electrode of two electrodes of the first smoothing capacitor are connected to ground,
a second end of the second switch, a second end of the fourth switch, a second end of the fifth switch, and a second end of the seventh switch are connected to a second electrode of the two electrodes of the first smoothing capacitor and a first electrode of two electrodes of the second smoothing capacitor,
a second end of the sixth switch, a second end of the eighth switch, a second end of the ninth switch, and a second end of the eleventh switch are connected to a second electrode of the two electrodes of the second smoothing capacitor and a first electrode of two electrodes of the third smoothing capacitor,
a second end of the tenth switch and a second end of the twelfth switch are connected to a second electrode of the two electrodes of the third smoothing capacitor,
a first end of the thirteenth switch is connected to the second electrode of the two electrodes of the first flying capacitor,
a second end of the thirteenth switch is connected to the first electrode of the two electrodes of the third flying capacitor,
a first end of the fourteenth switch is connected to the second electrode of the two electrodes of the second flying capacitor, and
a second end of the fourteenth switch is connected to the first electrode of the two electrodes of the fourth flying capacitor;
wherein:
the thirteenth switch and the fourteenth switch are controlled to be closed when the switched-capacitor circuit is in the first mode; and
the first switch, the second switch, the third switch, and the fourth switch are closed, and the thirteenth switch and the fourteenth switch are controlled to be open when the switched-capacitor circuit is in the second mode.

13. The tracker circuit according to claim 12, wherein:
when a peak-to-average power ratio (PAPR) of a radio frequency signal to be amplified by the power amplifier is lower than a threshold, the switched-capacitor circuit is configured to enter the first mode, and
when the PAPR is higher than or equal to the threshold, the first switch, the switched-capacitor circuit is configured to enter the second mode.

14. The tracker circuit according to claim 13,
wherein the switched-capacitor circuit further includes a fifth flying capacitor, a sixth flying capacitor, a fourth smoothing capacitor, a fifteenth switch, a sixteenth switch, a seventeenth switch, an eighteenth switch, a nineteenth switch, and a twentieth switch,
wherein:
the first end of the ninth switch and the first end of the tenth switch are switchably connected to the second electrode of the two electrodes of the third flying capacitor via the nineteenth switch, and are connected to a first electrode of two electrodes of the fifth flying capacitor,
the first end of the eleventh switch and the first end of the twelfth switch are switchably connected to the second electrode of the two electrodes of the fourth flying capacitor via the twentieth switch, and are connected to a first electrode of two electrodes of the sixth flying capacitor,
a first end of the fifteenth switch and a first end of the sixteenth switch are connected to a second electrode of the two electrodes of the fifth flying capacitor,
a first end of the seventeenth switch and a first end of the eighteenth switch are connected to a second electrode of the two electrodes of the sixth flying capacitor,
the second end of the tenth switch, the second end of the twelfth switch, a second end of the fifteenth switch, and a second end of the seventeenth switch are connected to the second electrode of the two electrodes of the third smoothing capacitor and a first electrode of two electrodes of the fourth smoothing capacitor,
a second end of the sixteenth switch and a second end of the eighteenth switch are connected to a second electrode of the two electrodes of the fourth smoothing capacitor,
a first end of the nineteenth switch is connected to the second electrode of the two electrodes of the third flying capacitor,
a second end of the nineteenth switch is connected to the first electrode of the two electrodes of the fifth flying capacitor,
a first end of the twentieth switch is connected to the second electrode of the two electrodes of the fourth flying capacitor, and
a second end of the twentieth switch is connected to the first electrode of the two electrodes of the sixth flying capacitor.

15. The tracker circuit according to claim 11,
wherein the switched-capacitor circuit includes a first flying capacitor, a second flying capacitor, a third flying capacitor, a fourth flying capacitor, a first smoothing capacitor, a second smoothing capacitor, a third smoothing capacitor, a first switch, a second switch, a third switch, a fourth switch, a fifth switch, a sixth switch, a seventh switch, an eighth switch, a ninth switch, a tenth switch, an eleventh switch, a twelfth switch, and a thirteenth switch,
wherein:
a first end of the first switch and a first end of the second switch are connected to a first electrode of two electrodes of the first flying capacitor,
a first end of the third switch and a first end of the fourth switch are connected to a first electrode of two electrodes of the second flying capacitor,
a first end of the fifth switch and a first end of the sixth switch are connected to a second electrode of the two electrodes of the first flying capacitor and a first electrode of two electrodes of the third flying capacitor,
a first end of the seventh switch and a first end of the eighth switch are connected to a second electrode of the two electrodes of the second flying capacitor and a first electrode of two electrodes of the fourth flying capacitor,
a first end of the ninth switch and a first end of the tenth switch are connected to a second electrode of the two electrodes of the third flying capacitor,
a first end of the eleventh switch and a first end of the twelfth switch are connected to a second electrode of the two electrodes of the fourth flying capacitor,
a second end of the first switch, a second end of the third switch, and a first electrode of two electrodes of the first smoothing capacitor are connected to each other,
a second end of the second switch, a second end of the fourth switch, a second end of the fifth switch, and a second end of the seventh switch are connected to a second electrode of the two electrodes of the first smoothing capacitor and a first electrode of two electrodes of the second smoothing capacitor,
a second end of the sixth switch, a second end of the eighth switch, a second end of the ninth switch, and a second end of the eleventh switch are connected to a second electrode of the two electrodes of the second smoothing capacitor and a first electrode of two electrodes of the third smoothing capacitor,
a second end of the tenth switch and a second end of the twelfth switch are connected to a second electrode of the two electrodes of the third smoothing capacitor, and
a first end and a second end of the thirteenth switch are respectively connected to the first electrode of the two electrodes of the first smoothing capacitor and the second electrode of the two electrodes of the first smoothing capacitor, the first electrode of the two electrodes of the second smoothing capacitor and the second electrode of the two electrodes of the second smoothing capacitor or the first electrode of the two electrodes of the third smoothing capacitor and the second electrode of the two electrodes of the third smoothing capacitor; and
wherein:
the thirteenth switch is controlled to be open when the switched-capacitor circuit is in the first mode; and
the fifth switch, the sixth switch, the seventh switch, and the eighth switch are controlled to be open, and the thirteenth switch is controlled to be closed when the switched-capacitor circuit is in the second mode.

16. The tracker circuit according to claim 15, wherein:
the first end of the thirteenth switch and the second end of the thirteenth switch are respectively connected to the first electrode of the two electrodes of the second smoothing capacitor and the second electrode of the two electrodes of the second smoothing capacitor,
when a peak-to-average power ratio (PAPR) of a radio frequency signal amplified by the power amplifier is lower than a threshold, the switched-capacitor circuit is configured to enter the first mode, and
when the PAPR is higher than or equal to the threshold, the switched-capacitor circuit is configured to enter the second mode.

17. The tracker circuit according to claim 11,
wherein the switched-capacitor circuit includes a first flying capacitor, a second flying capacitor, a third flying capacitor, a fourth flying capacitor, a first smoothing capacitor, a second smoothing capacitor, a third smoothing capacitor, a first switch, a second switch, a third switch, a fourth switch, a fifth switch, a sixth switch, a seventh switch, an eighth switch, a ninth switch, a tenth switch, an eleventh switch, a twelfth switch, a thirteenth switch, a fourteenth switch and a fifteenth switch,
wherein:
a first end of the first switch and a first end of the second switch are connected to a first electrode of two electrodes of the first flying capacitor,
a first end of the third switch and a first end of the fourth switch are connected to a first electrode of two electrodes of the second flying capacitor,
a first end of the fifth switch and a first end of the sixth switch are connected to a second electrode of the two electrodes of the first flying capacitor and a first electrode of two electrodes of the third flying capacitor,
a first end of the seventh switch and a first end of the eighth switch are connected to a second electrode of the two electrodes of the second flying capacitor and a first electrode of two electrodes of the fourth flying capacitor,
a first end of the ninth switch and a first end of the tenth switch are connected to a second electrode of the two electrodes of the third flying capacitor,
a first end of the eleventh switch and a first end of the twelfth switch are connected to a second electrode of the two electrodes of the fourth flying capacitor,
a second end of the first switch, a second end of the third switch, and a first electrode of two electrodes of the first smoothing capacitor are connected to each other,
a second end of the second switch, a second end of the fourth switch, a second end of the fifth switch, and a second end of the seventh switch are connected to a second electrode of the two electrodes of the first smoothing capacitor and a first electrode of two electrodes of the second smoothing capacitor,
a second end of the sixth switch, a second end of the eighth switch, a second end of the ninth switch, and a second end of the eleventh switch are connected to a second electrode of the two electrodes of the second smoothing capacitor and a first electrode of two electrodes of the third smoothing capacitor,
a second end of the tenth switch and a second end of the twelfth switch are connected to a second electrode of the two electrodes of the third smoothing capacitor,
a first end and a second end of the thirteenth switch are respectively connected to the first electrode of the two electrodes of the first smoothing capacitor and the second electrode of the two electrodes of the first smoothing capacitor, the first electrode of the two electrodes of the second smoothing capacitor and the second electrode of the two electrodes of the second smoothing capacitor or the first electrode of the two electrodes of the third smoothing capacitor and the second electrode of the two electrodes of the third smoothing capacitor,
the first end of the thirteenth switch and the second end of the thirteenth switch are respectively connected to the first electrode of the two electrodes of the second smoothing capacitor and the second electrode of the two electrodes of the second smoothing capacitor,
a first end of the fourteenth switch and a second end of the fourteenth switch are respectively connected to the first electrode of the two electrodes of the first flying capacitor and the second electrode of the two electrodes of the first flying capacitor, and
a first end of the fifteenth switch and a second end of the fifteenth switch are respectively connected to the first electrode of the two electrodes of the second flying capacitor and the second electrode of the two electrodes of the second flying capacitor; and
wherein:
the thirteenth switch, the fourteenth switch, and the fifteenth switch are controlled to be open when the switched-capacitor circuit is in the first mode; and
the fifth switch, the sixth switch, the seventh switch, and the eighth switch are controlled to be open, and the thirteenth switch, the fourteenth switch, and the fifteenth switch are controlled to be closed when the switched-capacitor circuit in the second mode.

18. The tracker circuit according to claim 17, wherein:
when a peak-to-average power ratio (PAPR) of a radio frequency signal amplified by the power amplifier is lower than a threshold, the switched-capacitor circuit is configured to enter the first mode; and
when the PAPR is higher than or equal to the threshold, the switched-capacitor circuit is configured to enter the second mode.

19. The tracker circuit according to claim 15, wherein:
the switched-capacitor circuit further includes a sixteenth switch,
the first end of the thirteenth switch and the second end of the thirteenth switch are respectively connected to the first electrode of the two electrodes of the second smoothing capacitor and the second electrode of the two electrodes of the second smoothing capacitor, and
a first end of the sixteenth switch and a second end of the sixteenth switch are respectively connected to the first electrode of the two electrodes of the third smoothing capacitor and the second electrode of the two electrodes of the third smoothing capacitor.

20. The tracker circuit according to claim 19, wherein:
the switched-capacitor circuit further includes a fourteenth switch and a fifteenth switch,
a first end of the fourteenth switch and a second end of the fourteenth switch are respectively connected to the first electrode of the two electrodes of the first flying capacitor and the second electrode of the two electrodes of the first flying capacitor, and
a first end of the fifteenth switch and a second end of the fifteenth switch are respectively connected to the first electrode of the two electrodes of the second flying capacitor and the second electrode of the two electrodes of the second flying capacitor.
